(19) United States
(12) Patent Application Publication
(10) Pub. No.: US 2025/0364761 A1
(43) Pub. Date: Nov. 27, 2025

(54) ELECTRICAL CONNECTOR ASSEMBLY WITH IMPROVED SHIELDING EFFECT

(71) Applicant: DONGGUAN LUXSHARE TECHNOLOGIES CO., LTD, Dongguan City (CN)

(72) Inventors: Bin HUANG, Dongguan City (CN); Chuanqi GONG, Dongguan City (CN); Kunlin YAO, Dongguan City (CN); Hongji CHEN, Dongguan City (CN)

(73) Assignee: DONGGUAN LUXSHARE TECHNOLOGIES CO., LTD, Dongguan City (CN)

(21) Appl. No.: 18/933,614

(22) Filed: Oct. 31, 2024

(30) Foreign Application Priority Data
May 27, 2024 (CN) 202410666566.1

(51) Int. Cl. H01R 13/6594; H01R 13/6587

(52) U.S. Cl. CPC H01R 13/6594; H01R 13/6587

(57) ABSTRACT

A connector assembly includes a first electrical connector and a shielding cage. The first electrical connector includes a conductive housing, a number of conductive terminals and a number of cables. The shielding cage includes a first receiving cavity. The first receiving cavity includes a first installation cavity and a first mating cavity. The first installation cavity is configured to at least partially receive the first electrical connector. The first mating cavity is configured to at least partially receive a first mating connector. The connector assembly further includes a retaining portion protruding into the first installation cavity. The retaining portion is configured to support the first electrical connector to partially retain the first electrical connector in the first installation cavity.

### CROSS-REFERENCE TO RELATED APPLICATION

This patent application claims priority of a Chinese Patent Application No. 202410666566.1, filed on May 27, 2024 and titled “ELECTRICAL CONNECTOR ASSEMBLY”, the entire content of which is incorporated herein by reference.

### TECHNICAL FIELD

The present disclosure relates to an electrical connector assembly, which belongs to the technical field of connectors.

### BACKGROUND

Connector assemblies in the related art include electrical connectors. The electrical connector includes an insulating body, a plurality of conductive terminals mounted to the insulating body, and a metal shell installed on the insulating body. The plurality of conductive terminals include a plurality of signal terminals. However, as the requirements for signal transmission quality of electrical connectors continue to increase, there is still room for improvement in electrical connectors in related technologies.

### SUMMARY

An object of the present disclosure is to provide an electrical connector assembly with improved shielding effect.

In order to achieve the above object, the present disclosure adopts the following technical solution: a connector assembly, including: a first electrical connector, the first electrical connector including: a conductive housing, the conductive housing defining a first receiving slot configured to at least partially receive a first mating connector along a first direction; a plurality of conductive terminals, the plurality of conductive terminals being at least partially disposed on the conductive housing; each conductive terminal including a contact arm; the contact arm including a contact portion that at least partially protrudes into the first receiving slot and is configured to be in electrical contact with the first mating connector; and a plurality of cables, the plurality of cables being electrically connected to the plurality of conductive terminals; a shielding cage, the shielding cage being configured to be mounted on a circuit board; the shielding cage defining a first receiving cavity surrounded by a plurality of walls; the first receiving cavity including a first installation cavity and a first mating cavity communicating with the first installation cavity along the first direction; the first installation cavity being configured to at least partially receive the first electrical connector; the first mating cavity being configured to at least partially receive the first mating connector; wherein the connector assembly further includes a retaining portion provided in the first installation cavity; the retaining portion is configured to support the first electrical connector to retain a portion of the first electrical connector that is located in the first installation cavity in the first installation cavity.

In order to achieve the above object, the present disclosure adopts the following technical solution: a connector assembly, including: a first electrical connector, the first electrical connector including: a conductive housing, the conductive housing defining a first receiving slot configured to at least partially receive a first mating connector along a first direction; a plurality of conductive terminals, the plurality of conductive terminals being at least partially assembled to the conductive housing; each conductive terminal including a contact arm; the contact arm including a contact portion that at least partially protrudes into the first receiving slot and is configured to be in electrical contact with the first mating connector; and a plurality of cables, the plurality of cables being electrically connected to the plurality of conductive terminals; a shielding cage, the shielding cage being configured to be mounted to a circuit board; the shielding cage defining a first receiving cavity surrounded by a plurality of walls; the first receiving cavity including a first installation cavity and a first mating cavity communicating with the first installation cavity along the first direction; the first installation cavity being configured to at least partially receive the first electrical connector along a second direction perpendicular to the first direction; the first mating cavity and the first receiving slot being configured to jointly at least partially receive the first mating connector; wherein the connector assembly further includes a retaining portion extending into the first installation cavity; the retaining portion is configured to clamp the first electrical connector to secure the first electrical connector in the first installation cavity.

Compared with the prior art, the connector assembly of the present disclosure includes the first electrical connector and the shielding cage. The first electrical connector includes the conductive housing. By providing the conductive housing instead of the insulating body in the related technology, the quality of signal transmission is improved. In addition, the shielding cage includes the first receiving cavity surrounded by the plurality of walls. The first electrical connector is at least partially received in the first receiving cavity. By providing the shielding cage, the shielding effect on the conductive terminals is further improved, and the quality of signal transmission is improved. Furthermore, the connector assembly further includes the retaining portion disposed in the first installation cavity. The retaining portion is configured to support the first electrical connector to retain the portion of the first electrical connector located in the first installation cavity, thereby improving the reliability of retaining the first electrical connector in the first installation cavity.

### BRIEF DESCRIPTION OF DRAWINGS

FIG. 1 is a perspective schematic view of a connector assembly in accordance with an embodiment of the present disclosure;

FIG. 2 is a perspective view of FIG. 1 from another angle;

FIG. 3 is a partially exploded perspective view of FIG. 1, in which a first module and a second module are separated from each other;

FIG. 4 is a partially exploded perspective view of FIG. 3 from another angle;

FIG. 5 is a partial enlarged view of a circled portion B in FIG. 3;

FIG. 6 is a partial enlarged view of a circled portion C in FIG. 4;

FIG. 7 is a top view of the first module and the second module when they are separated from each other;

FIG. 8 is a bottom view of FIG. 7;

FIG. 9 is a front view of a first electrical connector in FIG. 1;

FIG. 10 is a further partially exploded perspective view of FIG. 3;

FIG. 11 is a further partially exploded perspective view of FIG. 10;

FIG. 12 is a partially exploded perspective view of the first module;

FIG. 13 is a partially exploded perspective view of FIG. 12 from another angle;

FIG. 14 is a left view of FIG. 12;

FIG. 15 is a further partial perspective exploded view of the first module;

FIG. 16 is a partially exploded perspective view of the second module;

FIG. 17 is a partially exploded perspective view of FIG. 16 from another angle;

FIG. 18 is a left view of FIG. 16;

FIG. 19 is a further partial perspective exploded view of the second module;

FIG. 20 is a partial enlarged view of a circled portion E in FIG. 15;

FIG. 21 is a partial enlarged view of a circled portion G in FIG. 19;

FIG. 22 is a partial enlarged view of a frame portion D in FIG. 15;

FIG. 23 is a partial enlarged view of a frame portion F in FIG. 19;

FIG. 24 is a schematic cross-sectional view taken along line H-H in FIG. 9;

FIG. 25 is a perspective view of the electrical connector assembly in accordance with another embodiment of the present disclosure;

FIG. 26 is a perspective view of FIG. 25 from another angle;

FIG. 27 is a front view of FIG. 25;

FIG. 28 is a right view of FIG. 25;

FIG. 29 is a partially exploded perspective view of FIG. 25;

FIG. 30 is a partially exploded perspective view of FIG. 29 from another angle;

FIG. 31 is an exploded perspective view of a shielding cage in FIG. 29;

FIG. 32 is an exploded perspective view of FIG. 31 from another angle;

FIG. 33 is a schematic cross-sectional view taken along line J-J in FIG. 25;

FIG. 34 is a partial enlarged view of frame part K in FIG. 33;

FIG. 35 is a perspective view of a second electrical connector of the present disclosure when it is installed on a circuit board and a second mating module is inserted;

FIG. 36 is a front view of the second electrical connector shown in FIG. 35;

FIG. 37 is a right side view of the second electrical connector shown in FIG. 35;

FIG. 38 is a partially exploded perspective view of the second electrical connector shown in FIG. 35;

FIG. 39 is an exploded perspective view of a third conductive housing, a plurality of third terminal modules, a first insulating holding block and a third ground sheet in FIG. 38;

FIG. 40 is an exploded perspective view of FIG. 39 from another angle;

FIG. 41 is an exploded perspective view of a fourth conductive housing, a plurality of fourth terminal modules, a second insulating holding block and a fourth ground sheet in FIG. 38;

FIG. 42 is an exploded perspective view of FIG. 41 from another angle; and

FIG. 43 is a schematic cross-sectional view taken along line M-M in FIG. 35, in which the second mating module is not inserted into the second electrical connector.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

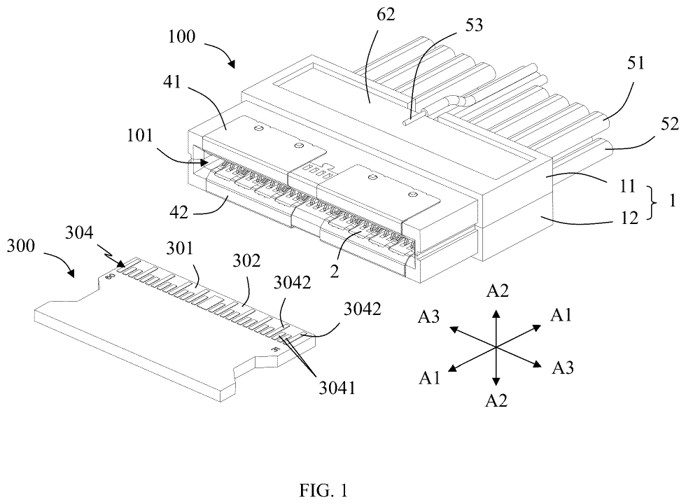

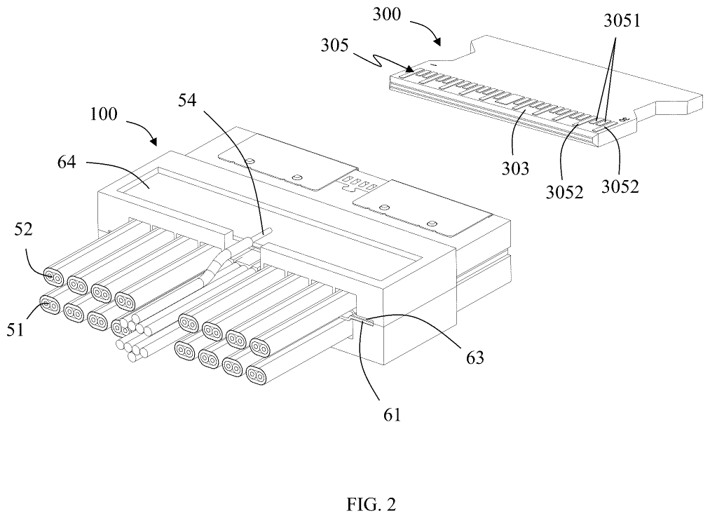

Referring to FIG. 1 and FIG. 2, a first embodiment of the present disclosure discloses a connector assembly including a first electrical connector 100 and a first mating module 300 configured to be at least partially inserted into the first electrical connector 100. In the illustrated embodiment of the present disclosure, the first electrical connector 100 is an OSFP (Octal Small Form-factor Pluggable) receptacle connector. More specifically, in the illustrated embodiment of the present disclosure, the first electrical connector 100 is a receptacle cable connector. Correspondingly, the first mating module 300 is an OSFP plug connector. Of course, it is understandable to those skilled in the art that the first electrical connector 100 can also be an SFP (Small Form-factor Pluggable) receptacle connector, a QSFP (Quad Small Form-factor Pluggable) receptacle connector, a QSFP-DD (Quad Small Form-factor Pluggable-Double Density) receptacle connector, an SFP-DD (Small Form-factor Pluggable-Double Density) receptacle connector or a DSFP (Dual Chanel Small Form-factor Pluggable) receptacle connector, etc. Correspondingly, the first mating module 300 is an SFP plug connector, a QSFP plug connector, a QSFP-DD plug connector, an SFP-DD plug connector or a DSFP plug connector, etc. It is understandable to those skilled in the art that the basic structure of the above types of the electrical connectors is regulated by corresponding association standards, and will not be described in detail here. Of course, it is understandable to those skilled in the art that the first electrical connector 100 can also be other types of electrical connectors, including but not limited to USB connectors, HDMI connectors, DisplayPort connectors, RJ45 connectors, Thunderbolt connectors, etc.

Referring to FIG. 1, in the illustrated embodiment of the present disclosure, the first electrical connector 100 defines a first receiving slot 101 for at least partially receiving the first mating module 300. To simplify the description of the specific embodiments of the present disclosure, an insertion and extraction direction of the first mating module 300 and the first electrical connector 100 is a first direction A1-A1 (for example, a front-rear direction); a thickness direction of the first receiving slot 101 is a second direction A2-A2 (for example, a top-bottom direction); a width direction of the first receiving slot 101 is a third direction A3-A3 (for example, a left-right direction). Each two of the first direction A1-A1, the second direction A2-A2 and the third direction A3-A3 are perpendicular to each other.

As shown in FIG. 1 and FIG. 2, the first mating module 300 includes a tongue plate 301. The tongue plate 301 includes a tongue plate upper surface 302, a tongue plate lower surface 303, a plurality of first contact pads 304 exposed to the tongue plate upper surface 302, and a plurality of second contact pads 305 exposed to the tongue plate lower surface 303. The plurality of first contact pads 304 are disposed at intervals along the third direction A3-A3. The plurality of second contact pads 305 are disposed at intervals along the third direction A3-A3.

Specifically, in the illustrated embodiment of the present disclosure, the plurality of first contact pads 304 include a plurality of first signal contact pads 3041 and a plurality of first ground contact pads 3042. The plurality of first signal contact pads 3041 are divided into a plurality of groups, in which each group includes two first signal contact pads 3041 adjacently arranged along the third direction A3-A3. Each group of first signal contact pads 3041 is associated with two first ground contact pads 3042 which are located on two sides thereof respectively, so as to improve shielding and improve signal transmission quality. In the illustrated embodiment of the present disclosure, each group of first signal contact pads 3041 forms a differential pair to increase the speed of signal transmission. In the illustrated embodiment of the present disclosure, a length of each first ground contact pad 3042 along the first direction A1-A1 is greater than a length of each first signal contact pad 3041 along the first direction A1-A1, so as to better improve the shielding and improve the signal transmission quality.

Similarly, in the illustrated embodiment of the present disclosure, the plurality of second contact pads 305 include a plurality of second signal contact pads 3051 and a plurality of second ground contact pads 3052. The plurality of second signal contact pads 3051 are divided into a plurality of groups, in which each group includes two second signal contact pads 3051 adjacently arranged along the third direction A3-A3. Each group of second signal contact pads 3051 is associated with two second ground contact pads 3052 which are located on two sides thereof respectively, so as to improve shielding and improve signal transmission quality. In the illustrated embodiment of the present disclosure, each group of second signal contact pads 3051 forms a differential pair to increase the speed of signal transmission. In the illustrated embodiment of the present disclosure, a length of each second ground contact pad 3052 along the first direction A1-A1 is greater than a length of each second signal contact pad 3051 along the first direction A1-A1, so as to better improve the shielding and improve the signal transmission quality.

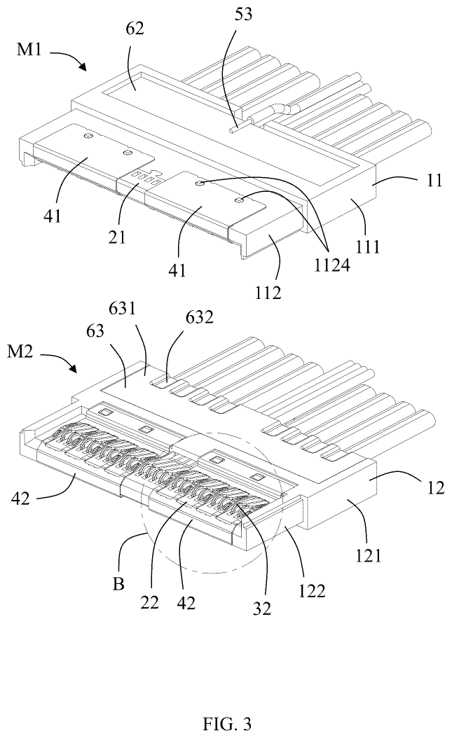

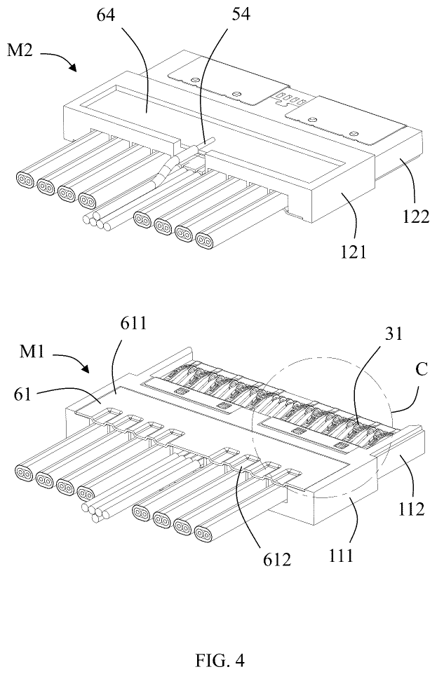

Referring to FIG. 1 to FIG. 4, in the illustrated embodiment of the present disclosure, the first electrical connector 100 includes a first module M1 and a second module M2. The first module M1 and the second module M2 are separately arranged and fixed together. Preferably, the first module M1 and the second module M2 are the same part, but have different installation angles to save costs.

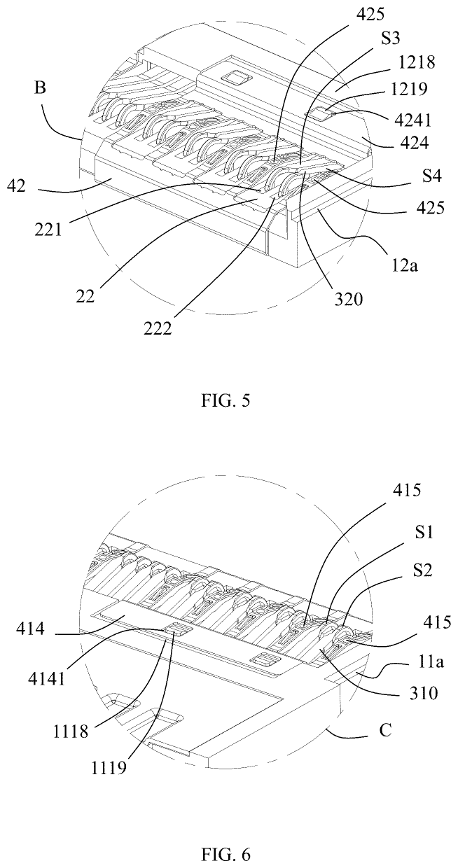

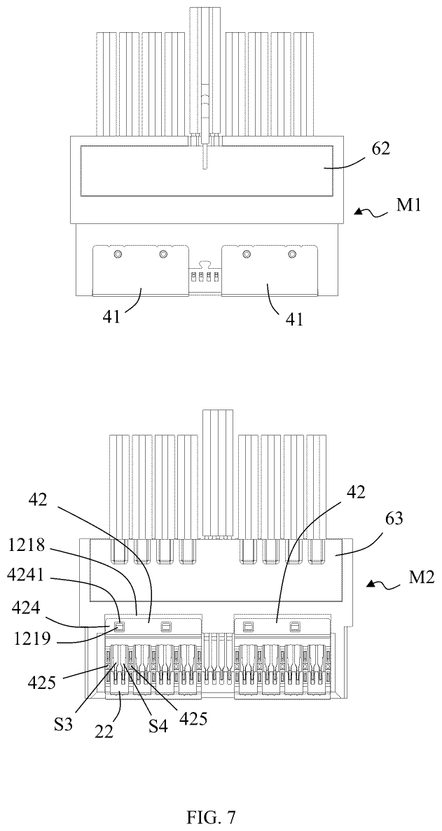

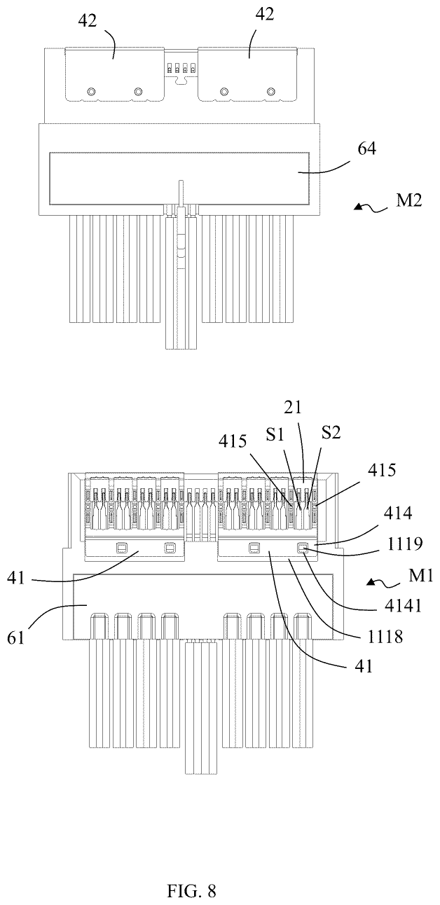

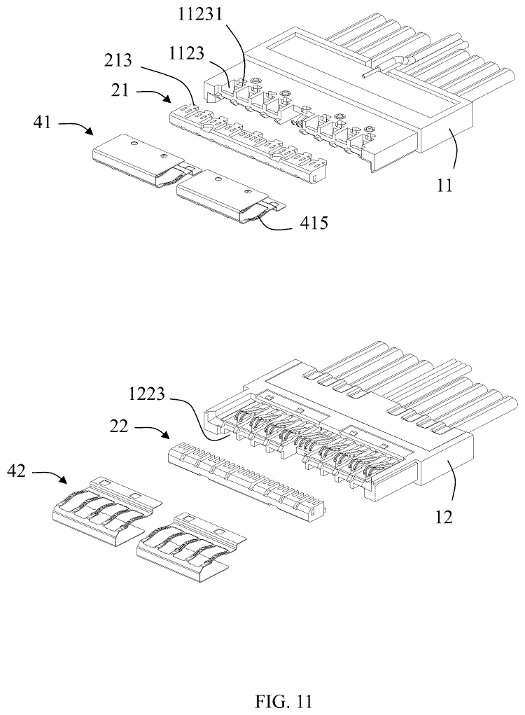

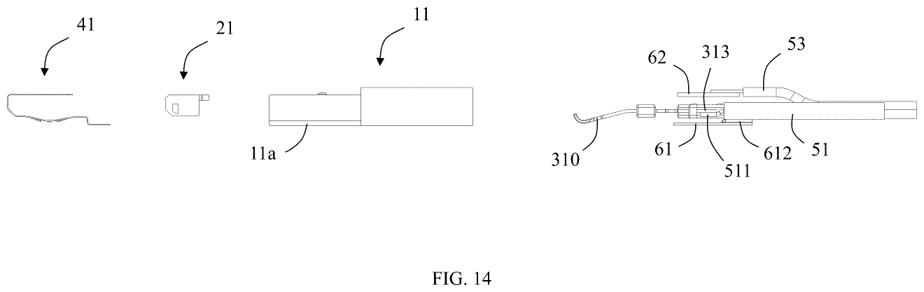

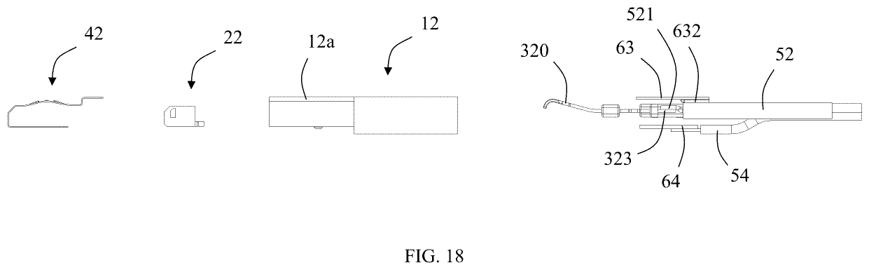

Referring to FIGS. 1 to 23, in one embodiment of the present disclosure, the first electrical connector 100 includes a housing, an insulating fixing block 2 fixed to the housing, and a plurality of conductive terminals 3 installed to the housing.

In an embodiment of the present disclosure, the housing is a conductive housing 1. The conductive housing 1 is a metal housing made of metal material so as to further improve the shielding effect and improve the quality of signal transmission. In another embodiment of the present disclosure, the conductive housing 1 may also be a composite housing formed by electroplating a metal material on an insulating material. The composite housing can also improve the shielding effect and improve the quality of signal transmission.

As shown in FIG. 1 to FIG. 6, in an embodiment of the present disclosure, the conductive housing 1 includes a first conductive housing 11 and a second conductive housing 12. The first conductive housing 11 and the second conductive housing 12 are fixed together. For example, after the first conductive housing 11 and the second conductive housing 12 are assembled, they are fixed together for example by welding or soldering or other methods. In the illustrated embodiment of the present disclosure, the first conductive housing 11 of the first module M1 and the second conductive housing 12 of the second module M2 are separately arranged and fixed together to jointly form the first receiving slot 101.

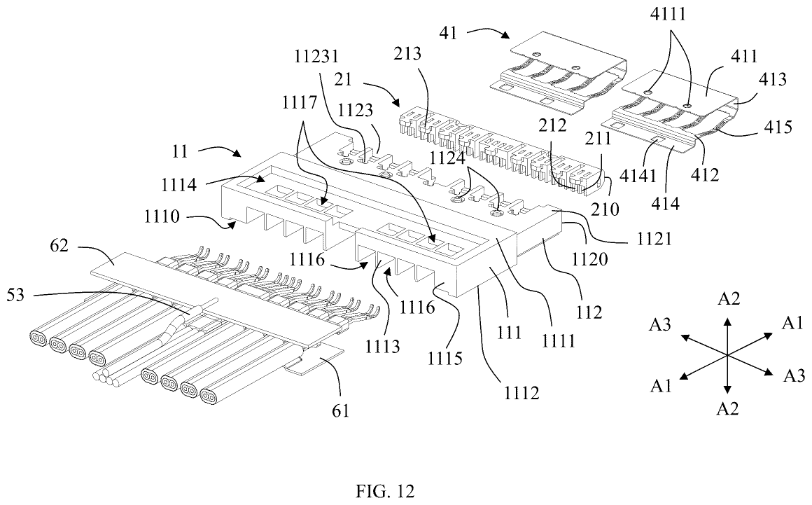

Referring to FIG. 12 to FIG. 15, in an embodiment of the present disclosure, the first conductive housing 11 includes a first base portion 111 and a first protruding portion 112 extending forwardly from the first base portion 111. The first base portion 111 includes a first upper surface 1111, a first lower surface 1112, a first rear surface 1115 and a plurality of first mounting grooves 1116 recessed forwardly from the first rear surface 1115. The plurality of first mounting grooves 1116 are spaced apart along the third direction A3-A3. Besides, the plurality of first mounting grooves 1116 extend downwardly through the first lower surface 1112. In the illustrated embodiment of the present disclosure, the first base portion 111 is further provided with a plurality of first barrier portions 1113. Any two adjacent first mounting grooves 1116 are separated by one first barrier portion 1113 located between the two first mounting grooves 1116 so as to improve the shielding effect and improve the quality of signal transmission. The first base portion 111 further defines a first receiving recess 1114 formed downwardly from the first upper surface 1111, a first mounting recess 1110 formed upwardly from the first lower surface 1112, and a plurality of first through holes 1117 communicating the first receiving recess 1114 and the plurality of first mounting grooves 1116 along the second direction A2-A2. The plurality of first through holes 1117 extend upwardly through the first upper surface 1111. In the illustrated embodiment of the present disclosure, the plurality of first through holes 1117 and the plurality of first mounting grooves 1116 are disposed in a one-to-one correspondence manner, and each first through hole 1117 communicates with a corresponding first mounting groove 1116 along the second direction A2-A2. Specifically, in the illustrated embodiment of the present disclosure, the first mounting grooves 1116 extend backwardly through the first rear surface 1115. The first mounting grooves 1116 communicate downwardly with the first mounting recess 1110. The first mounting recess 1110 extends downwardly through the first lower surface 1112. The first mounting grooves 1116 upwardly communicate with the first receiving recess 1114 through the first through holes 1117. The first receiving recess 1114 extends upwardly through the first upper surface 1111. Besides, a bottom of the first base portion 111 further includes at least one first recess 1118 adjacent to the first protruding portion 112. In the illustrated embodiment of the present disclosure, two first recesses 1118 are provided. The first base portion 111 further includes a plurality of first mounting protrusions 1119 protruding into corresponding first recesses 1118.

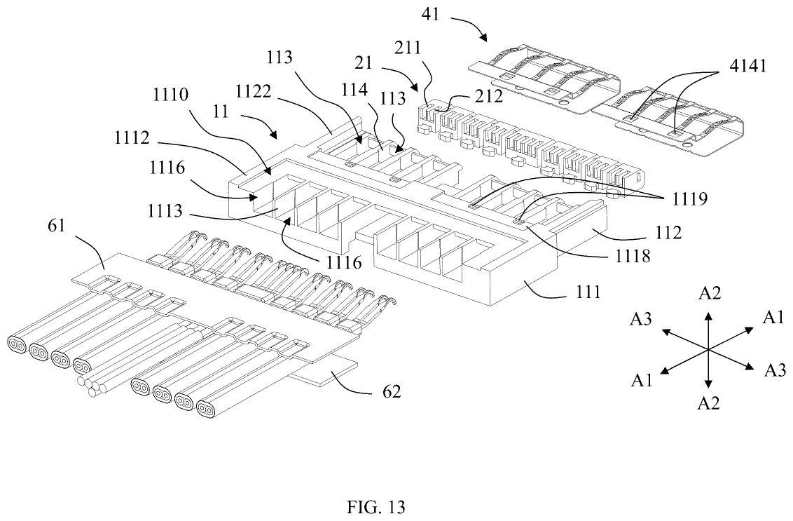

Referring to FIG. 12 and FIG. 13, the first protruding portion 112 includes a second upper surface 1121, a second lower surface 1122, and a plurality of first filling grooves 1123 extending upwardly through the second upper surface 1121 along the second direction A2-A2. The first filling grooves 1123 extend forwardly through a first front end surface 1120 of the first protruding portion 112 along the first direction A1-A1. The first protruding portion 112 further includes a plurality of first positioning posts 1124 protruding upwardly beyond the second upper surface 1121 along the second direction A2-A2.

Referring to FIG. 13, in the illustrated embodiment of the present disclosure, the first conductive housing 11 further includes a plurality of first terminal module installation slots 113 extending along the first direction A1-A1. Each first terminal module installation slot 113 extends from a portion of the first base portion 111 to the first protruding portion 112. A rear end of the first terminal module installation slot 113 communicates with the first mounting groove 1116. A middle portion of the first terminal module installation slot 113 is circumferentially surrounded by walls of the first conductive housing 11. A front end of the first terminal module installation slot 113 extends downwardly through the second lower surface 1122. Specifically, in the illustrated embodiment of the present disclosure, the first terminal module installation slot 113 includes a first surrounding groove 1131 close to a corresponding first mounting groove 1116 and a first open slot 1132 away from the corresponding first mounting groove 1116. The first surrounding groove 1131 is surrounded by wall portions of the first conductive housing 11 along a circumferential direction. The first open slot 1132 communicates with the first receiving slot 101. It is understandable to those skilled in the art that by arranging the middle portion of the first terminal module installation slot 113 to be surrounded by the wall portions of the first conductive housing 11 in a circumferential direction, on the one hand, the conductive terminals located in the first terminal module installation slots 113 can be better shielded; and on the other hand, adjacent first terminal module installation slots 113 can be well separated, thereby reducing signal crosstalk.

As shown in FIG. 13, the plurality of first terminal module installation slots 113 are spaced apart along the third direction A3-A3. The first conductive housing 11 includes a plurality of first partition walls 114 disposed at intervals along the third direction A3-A3. Two adjacent first terminal module installation slots 113 are separated by a corresponding first partition wall 114 along the third direction A3-A3. In other words, each first terminal module installation slot 113 is surrounded by four walls of the first conductive housing 11 on a length corresponding to the corresponding first partition wall 114, thereby improving the shielding effect. With this arrangement, each first terminal module installation slot 113 is relatively independent, thereby reducing signal crosstalk and improving the quality of data transmission.

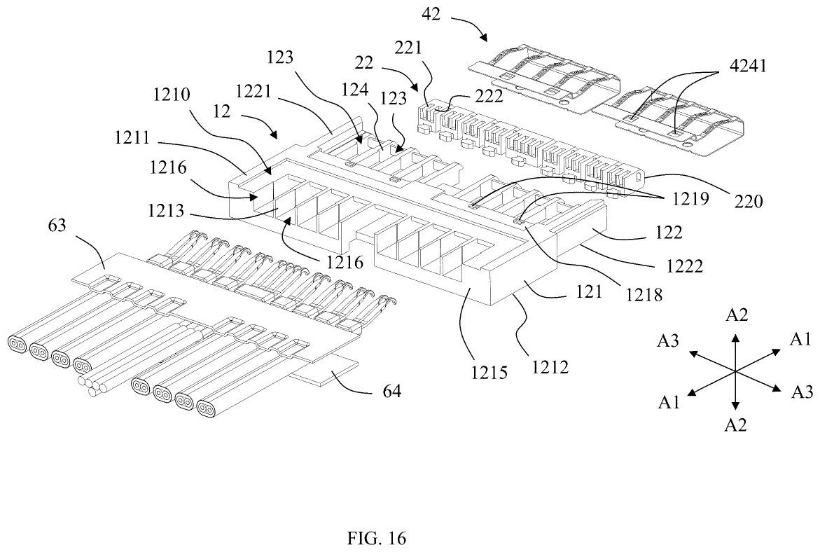

Referring to FIG. 16 to FIG. 19, in an embodiment of the present disclosure, the second conductive housing 12 includes a second base portion 121 and a second protruding portion 122 extending forwardly from the second base portion 121. The second base portion 121 includes a third upper surface 1211, a third lower surface 1212, a second rear surface 1215 and a plurality of second mounting grooves 1216 recessed forwardly from the second rear surface 1215. The plurality of second mounting grooves 1216 are spaced apart along the third direction A3-A3. The plurality of second mounting grooves 1216 extend through the second base portion 121 along the top-bottom direction. The plurality of second mounting grooves 1216 extend upwardly through the third upper surface 1211. In the illustrated embodiment of the present disclosure, the second base portion 121 is further provided with a plurality of second barrier portions 1213. Any two adjacent second mounting grooves 1216 are separated by one second barrier portion 1213 located between the two second mounting grooves 1216 to improve the shielding effect and improve the quality of signal transmission. The second base portion 121 further defines a second receiving recess 1214 formed upwardly from the third lower surface 1212, a second mounting recess 1210 formed downwardly from the third upper surface 1211, and a plurality of second through holes 1217 communicating with the second receiving recess 1214 and the plurality of second mounting grooves 1216. The plurality of second through holes 1217 extend downwardly through the third lower surface 1212. In the illustrated embodiment of the present disclosure, the plurality of second through holes 1217 and the plurality of second mounting grooves 1216 are disposed in a one-to-one correspondence manner, and each second through hole 1217 communicates with a corresponding second mounting groove 1216 along the second direction A2-A2. Specifically, in the illustrated embodiment of the present disclosure, the second mounting grooves 1216 extend backwardly through the second rear surface 1215. The second mounting grooves 1216 upwardly communicate with the second mounting recess 1210. The second mounting recess 1210 extends upwardly through the third upper surface 1211. The second mounting grooves 1216 communicate downwardly with the second receiving recess 1214 through the second through holes 1217. The second receiving recess 1214 extends downwardly through the third lower surface 1212. Besides, a top of the second base portion 121 further defines at least one second recess 1218 adjacent to the second protruding portion 122. In the illustrated embodiment of the present disclosure, two second recesses 1218 are provided. The second base portion 121 further includes a plurality of second mounting protrusions 1219 protruding into corresponding second recesses 1218.

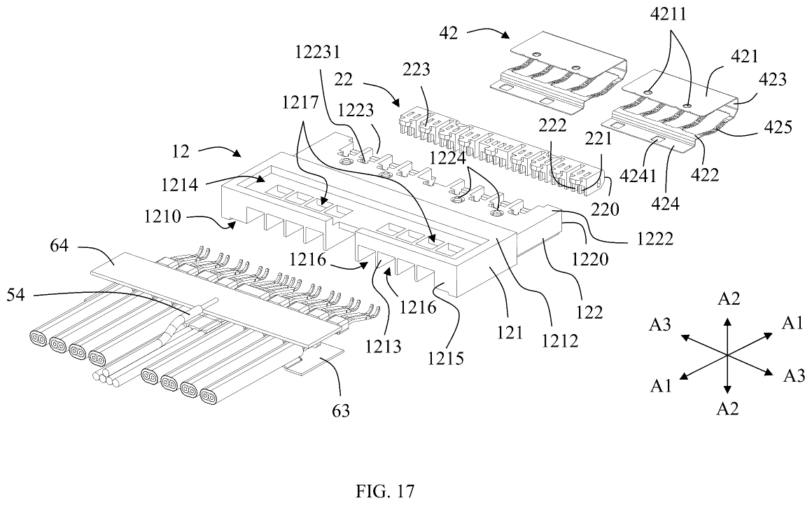

Referring to FIG. 16 and FIG. 17, the second protruding portion 122 includes a fourth upper surface 1221, a fourth lower surface 1222, and a plurality of second filling grooves 1223 extending downwardly through the fourth lower surface 1222. The second filling grooves 1223 extend forwardly through a second front end surface 1220 of the second protruding portion 122. The second protruding portion 122 further includes a plurality of second positioning posts 1224 protruding downwardly beyond the second lower surface 1122.

Referring to FIG. 16, in the illustrated embodiment of the present disclosure, the second conductive housing 12 further includes a plurality of second terminal module installation slots 123 extending along the first direction A1-A1. Each second terminal module installation slot 123 extends from the second base portion 121 to the second protruding portion 122. A rear end of the second terminal module installation slot 123 communicates with the second mounting groove 1216. The middle portion of the second terminal module installation slot 123 is circumferentially surrounded by walls of the second conductive housing 12. A front end of the second terminal module installation slot 123 extends upwardly through the fourth upper surface 1221. Specifically, in the illustrated embodiment of the present disclosure, the second terminal module installation slot 123 includes a second surrounding groove 1231 close to a corresponding second mounting groove 1216 and a second open slot 1232 away from the corresponding second mounting groove 1216. The second surrounding groove 1231 is surrounded by wall portions of the second conductive housing 12 along a circumferential direction. The second open slot 1232 communicates with the first receiving slot 101. It is understandable to those skilled in the art that by arranging the middle portion of the second terminal module installation slot 123 to be surrounded by the wall portions of the second conductive housing 12 in a circumferential direction; on the one hand, the conductive terminals located in the second terminal module installation slots 123 can be better shielded; and on the other hand, the adjacent second terminal module installation slots 123 can be well separated, thereby reducing signal crosstalk.

As shown in FIG. 16, the plurality of second terminal module installation slots 123 are arranged at intervals along the third direction A3-A3. The second conductive housing 12 includes a plurality of second partition walls 124 disposed at intervals along the third direction A3-A3. Two adjacent second terminal module installation slots 123 are separated by corresponding second partition walls 124 along the third direction A3-A3. In other words, each second terminal module installation slot 123 is surrounded by four walls of the second conductive housing 12 on a length corresponding to the second partition wall 124, thereby improving the shielding effect. With this arrangement, each second terminal module installation slot 123 is relatively independent, thereby reducing signal crosstalk and improving the quality of data transmission.

Referring to FIG. 1 to FIG. 19, in the illustrated embodiment of the present disclosure, the insulating fixing block 2 includes a first insulating fixing block 21 and a second insulating fixing block 22. The first insulating fixing block 21 is fixed in the first filling grooves 1123. The second insulating fixing block 22 is fixed in the second filling grooves 1223. Preferably, in order to increase the bonding force between the first insulating fixing block 21 and the first conductive housing 11, the first insulating fixing block 21 is molded in the first filling grooves 1123. Similarly, in order to increase the bonding force between the second insulating fixing block 22 and the second conductive housing 12, the second insulating fixing block 22 is molded in the second filling grooves 1223. The first insulating fixing block 21 is provided with a first dovetail protrusion 213. The first filling groove 1123 is provided with a first dovetail groove 11231. When the first dovetail protrusion 213 is clamped into the first dovetail groove 11231, the first insulating fixing block 21 can be prevented from falling off from the first conductive housing 11 in the first direction A1-A1. Similarly, the second insulating fixing block 22 is provided with a second dovetail protrusion 223. The second filling groove 1223 is provided with a second dovetail groove 12231. When the second dovetail protrusion 223 is clamped into the second dovetail groove 12231, the second insulating fixing block 22 can be prevented from falling off from the second conductive housing 12 in the first direction A1-A1.

The first insulating fixing block 21 defines a plurality of first slits 211 and a plurality of second slits 212, in which adjacent first slit 211 and second slit 212 form a group and communicate with a corresponding first terminal module installation slot 113. The first insulating fixing block 21 further includes a first front surface 210 which is coplanar with the first front end surface 1120 of the first protruding portion 112.

Similarly, the second insulating fixing block 22 defines a plurality of third slits 221 and a plurality of fourth slits 222. Adjacent third slit 221 and fourth slit 222 form a group and communicate with a corresponding second terminal module installation slot 123. The second insulating fixing block 22 includes a second front surface 220 which is coplanar with the second front end surface 1220 of the second protruding portion 122.

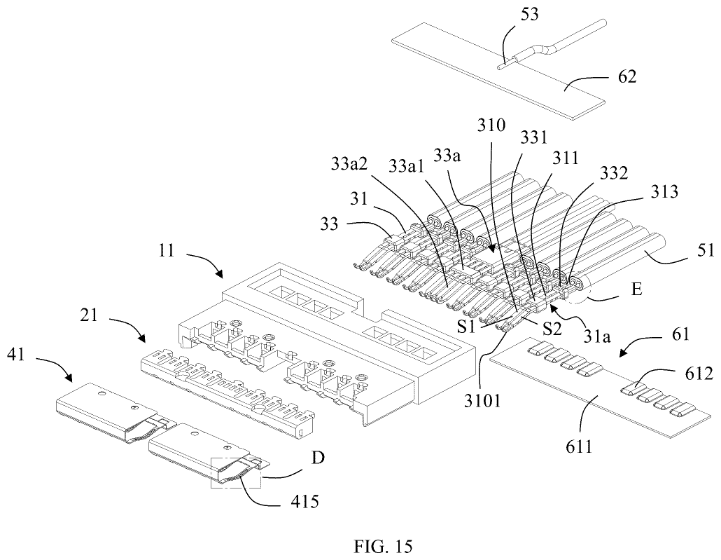

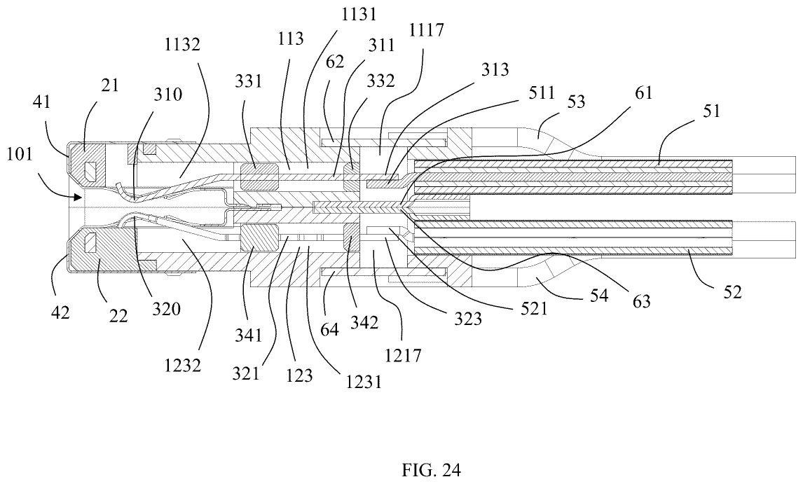

As shown in FIG. 15 to FIG. 24, the plurality of conductive terminals 3 include a plurality of first conductive terminals 31 and a plurality of second conductive terminals 32. Each first conductive terminal 31 includes a first fixing portion 311 extending along the first direction A1-A1, a first contact arm 310 extending forwardly from a front end of the first fixing portion 311, and a first tail portion 313 extending backwardly from a rear end of the first fixing portion 311. The first fixing portion 311 is at least partially located in the first surrounding groove 1131. The first contact arm 310 is at least partially located in the first open slot 1132. The first tail portion 313 is at least partially located in the first mounting groove 1116. The first contact arm 310 includes a first contact portion 3101 that passes through the first open slot 1132 and extends into the first receiving slot 101. The first contact portions 3101 are configured to be in contact with the first signal contact pads 3041 of the tongue plate 301. In the illustrated embodiment of the present disclosure, the first tail portions 313 extend backwardly and horizontally to be electrically connected to first cables 51.

Referring to FIG. 15, in the illustrated embodiment of the present disclosure, the plurality of first conductive terminals 31 are divided into a plurality of groups. Each group of first conductive terminals 31 includes a first signal terminal SI and a second signal terminal S2 located adjacent to the first signal terminal S1. Preferably, the first signal terminal S1 and the second signal terminal S2 in each group of first conductive terminals 31 form a differential pair to improve signal transmission speed, thereby being suitable for high-speed signal transmission.

In the illustrated embodiment of the present disclosure, the first electrical connector 100 further includes a first holding block 33 fixed on the first signal terminal SI and the second signal terminal S2 of each group of first conductive terminals 31. In an embodiment of the present disclosure, the first signal terminal SI and the second signal terminal S2 are insert-molded with the first holding block 33, so as to form an integrated first terminal module 31a. The first contact portions 3101 of the first signal terminal S1 and the second signal terminal S2 in each first terminal module 31a are configured to be in contact with the first signal contact pads 3041 of the first mating module 300, respectively.

In the illustrated embodiment of the present disclosure, the first holding block 33 includes a first fixing block 331 fixed on middle portions of the first fixing portions 311 of the first signal terminal S1 and the second signal terminal S2, and a second fixing block 332 fixed on rear ends of the first fixing portions 311 of the first signal terminal S1 and the second signal terminal S2. The first fixing block 331 and the second fixing block 332 are installed and fixed in the first terminal module installation slot 113, which prevents the first conductive terminal 31 from contacting the first conductive housing 11 to cause a short circuit. The first tail portion 313 extends backwardly into the first mounting groove 1116 to facilitate connection with the first cable 51.

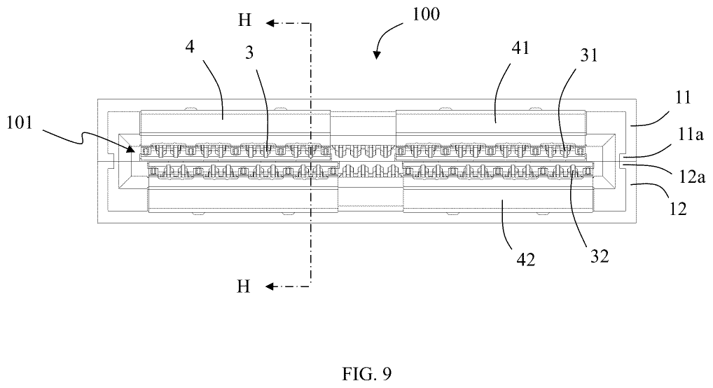

Similarly, referring to FIG. 9, each second conductive terminal 32 includes a second fixing portion 321 extending along the first direction A1-Al, a second contact arm 320 extending forwardly from a front end of the second fixing portion 321, and a second tail portion 323 extending backwardly from a rear end of the second fixing portion 321. The second fixing portion 321 is at least partially located in the second surrounding groove 1231. The second contact arm 320 is located at least partially in the second open slot 1232. The second tail portion 323 is at least partially located in the second mounting groove 1216. The second contact arm 320 includes a second contact portion 3201 that passes through the second open slot 1232 and extends into the first receiving slot 101. The second contact portions 3201 are configured to be in contact with the second signal contact pads 3051 of the tongue plate 301. In the illustrated embodiment of the present disclosure, the second tail portions 323 extend backwardly and horizontally from the second fixing portions 321 to be electrically connected to second cables 52.

In the illustrated embodiment of the present disclosure, the plurality of second conductive terminals 32 are divided into a plurality of groups, and each group of second conductive terminals 32 includes a third signal terminal S3 and a fourth signal terminal S4 located adjacent to the third signal terminal S3. Preferably, the third signal terminal S3 and the fourth signal terminal S4 in each group of second conductive terminals 32 form a differential pair to improve signal transmission speed, thereby being suitable for high-speed signal transmission.

In the illustrated embodiment of the present disclosure, the first electrical connector 100 further includes a second holding block 34 fixed on the third signal terminal S3 and the fourth signal terminal S4 of each group of second conductive terminals 32. In one embodiment of the present disclosure, the third signal terminal S3 and the fourth signal terminal S4 are insert-molded with the second holding block 34 to form an integrated second terminal module 32a. The second contact portions 3201 of the third signal terminal S3 and the fourth signal terminal S4 in each second terminal module 32a are configured to be in contact with the second signal contact pads 3051 of the first mating module 300.

In the illustrated embodiment of the present disclosure, the second holding block 34 includes a third fixing block 341 fixed at middle portions of the second fixing portions 321 of the third signal terminal S3 and the fourth signal terminal S4, and a fourth fixing block 342 fixed at rear ends of the second fixing portions 321 of the third signal terminal S3 and the fourth signal terminal S4. The third fixing block 341 and the fourth fixing block 342 are installed and fixed in the second terminal module installation slot 123, which prevents the second conductive terminal 32 from contacting the second conductive housing 12 to cause a short circuit. The second tail portions 323 extend backwardly into the second mounting grooves 1216 to facilitate connection with the second cables 52.

As shown in FIG. 15, in the illustrated embodiment of the present disclosure, the first electrical connector 100 further includes a first non-high-speed terminal module 33a and a second non-high-speed terminal module 34a. The first non-high-speed terminal module 33a includes a first insulating block 33a1 and a plurality of first non-high-speed terminals 33a2 fixed to the first insulating block 33a1. It is understandable to those skilled in the art that the first non-high-speed terminals 33a2 include but are not limited to non-high-speed signal terminals, power terminals, etc.

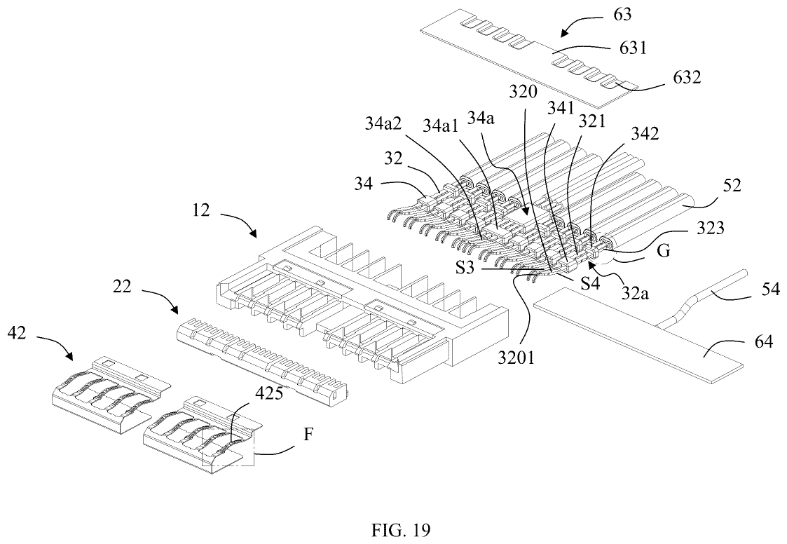

Similarly, as shown in FIG. 19, the second non-high-speed terminal module 34a includes a second insulating block 34a1 and a plurality of second non-high-speed terminals 34a2 fixed to the second insulating block 34a1. It is understandable to those skilled in the art that the second non-high-speed terminals 34a2 include but are not limited to non-high-speed signal terminals, power terminals, etc.

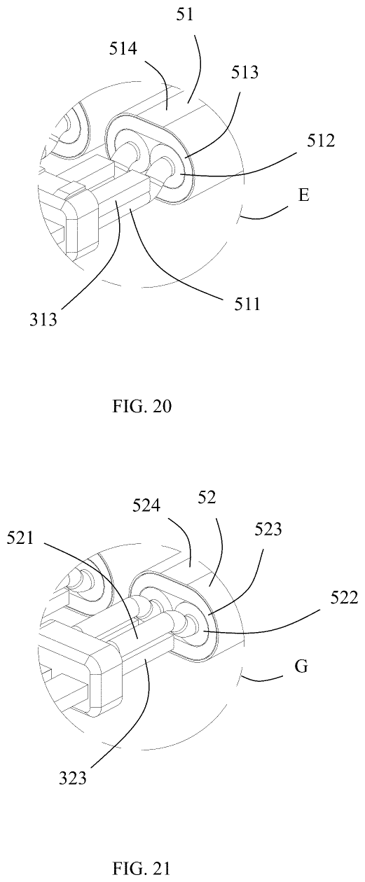

Referring to FIG. 20, in the illustrated embodiment of the present disclosure, the first cable 51 includes a first core 511, a first insulator 512 wrapped around the first core 511, a first shielding layer 513 (such as a shielding braid) wrapped around the first insulator 512, and a first insulation skin 514 wrapped around the first shielding layer 513.

Similarly, as shown in FIG. 21, the second cable 52 includes a second core 521, a second insulator 522 wrapped around the second core 521, a second shielding layer 523 (such as a shielding braid) wrapped around the second insulator 522, and a second insulation skin 524 wrapped around the second shielding layer 523.

Referring to FIG. 1 to FIG. 24, in one embodiment of the present disclosure, the first electrical connector 100 further includes at least one ground sheet 4 mounted to the conductive housing 1. The ground sheet 4 includes a first ground sheet 41 and a second ground sheet 42. In the illustrated embodiment of the present disclosure, two first ground sheets 41 are provided and they are made of metal material. Two second ground sheets 42 are provided and they are made of metal material.

Referring to FIG. 12 and FIG. 13, each first ground sheet 41 is generally U-shaped and includes a first mounting plate 411, a second mounting plate 412 opposite to the first mounting plate 411, a first connecting plate 413 connecting one side of the first mounting plate 411 and one side of the second mounting plate 412, and a first extension plate 414 extending downwardly and backwardly from another side of the second mounting plate 412. The first mounting plate 411 defines a plurality of first mounting positioning holes 4111 that match the first positioning posts 1124. The first extension plate 414 is received in a corresponding first recess 1118 of the first conductive housing 11. The first extension plate 414 defines a plurality of first mounting holes 4141 to receive the first mounting protrusions 1119.

The first connecting plate 413 abuts against and at least partially covers the first front surface 210 of the first insulating fixing block 21. The first connecting plate 413 is located at a front end of the first receiving slot 101 along the first direction A1-A1. When the first mating module 300 is inserted, the tongue plate 301 may be in contact with the first connecting plate 413 first, thereby facilitating the discharge of static electricity. The second mounting plate 412 is provided with a plurality of first grounding elastic arms 415 which are disposed at intervals along the third direction A3-A3. The first grounding elastic arms 415 are disposed on two sides of the first contact arms 310 of each group of first conductive terminals 31 so as to improve the shielding effect and improve the quality of signal transmission.

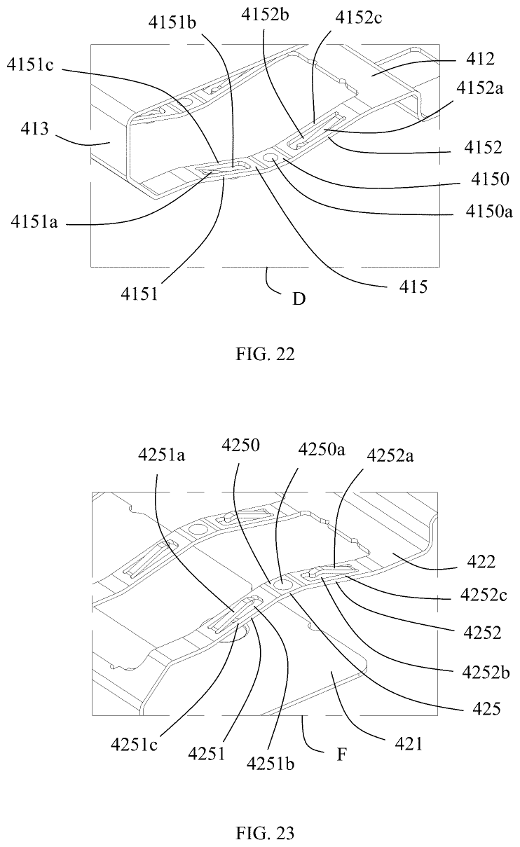

Referring to FIG. 22, the first grounding elastic arm 415 as a whole bulges away from the first mounting plate 411. Specifically, in the illustrated embodiment of the present disclosure, the first grounding elastic arm 415 includes a first intermediate portion 4150, a first elastic arm portion 4151 connecting one end of the first intermediate portion 4150 and the first connecting plate 413, and a second elastic arm portion 4152 connecting another end of the first intermediate portion 4150 and the first extension plate 414. In one embodiment of the present disclosure, the first intermediate portion 4150 includes a first dimple 4150a protruding into the first receiving slot 101. The first elastic arm portion 4151 is provided with a first contact elastic arm 4151a extending toward the first intermediate portion 4150, and a first relief groove 4151b corresponding to the first contact elastic arm 4151a and providing a deformation space for the first contact elastic arm 4151a. The second elastic arm portion 4152 is provided with a second contact elastic arm 4152a extending toward the first intermediate portion 4150, and a second relief groove 4152b corresponding to the second contact elastic arm 4152a and providing a deformation space for the second contact elastic arm 4152a. In the illustrated embodiment of the present disclosure, the first contact elastic arm 4151a and the second contact elastic arm 4152a are located on two sides of the first intermediate portion 4150, respectively. The first contact elastic arm 4151a and the second contact elastic arm 4152a are aligned along the first direction A1-A1. A free end of the first contact elastic arm 4151a and a free end of the second contact elastic arm 4152a are both located adjacent to the first intermediate portion 4150. The first contact elastic arm 4151a, the first dimple 4150a and the second contact elastic arm 4152a are all in contact with the corresponding first ground contact pad 3042 of the first mating module 300. This three-point contact method is beneficial to achieve better shielding effect.

In one embodiment of the present disclosure, the first elastic arm portion 4151 includes a first frame 4151c that is surrounded by all sides. The first relief groove 4151b is a closed groove and is surrounded by the first frame 4151c. The first contact elastic arm 4151a is connected to a wall of the first frame 4151c. The other three walls of the first frame 4151c respectively surround the other three sides of the first contact elastic arm 4151a. In an embodiment of the present disclosure, by arranging the first frame 4151c surrounding the first contact elastic arm 4151a, it can provide better protection for the first contact elastic arm 4151a and prevent the first contact elastic arm 4151a from being excessively deformed.

Similarly, the second elastic arm portion 4152 includes a second frame 4152c that is surrounded by all sides. The second relief groove 4152b is a closed groove and is surrounded by the second frame 4152c. The second contact elastic arm 4152a is connected to a wall of the second frame 4152c. The other three walls of the second frame 4152c respectively surround the other three sides of the second contact elastic arm 4152a. In one embodiment of the present disclosure, by arranging the second frame 4152c surrounding the second contact elastic arm 4152a, it can provide better protection for the second contact elastic arm 4152a and prevent the second contact elastic arm 4152a from being excessively deformed.

In an embodiment of the present disclosure, the first positioning posts 1124 are fixed to the first mounting positioning holes 4111, so that the first mounting plate 411 is fixed to the second upper surface 1121 of the first protruding portion 112. As shown in FIG. 21, a dimension of the first mounting hole 4141 along the first direction A1-A1 may be slightly larger than a dimension of the first mounting protrusion 1119 along the first direction A1-A1. Therefore, when the first contact elastic arm 4151a, the first intermediate portion 4150 and the second contact elastic arm 4152a are contacted and deformed by the first ground contact pad 3042 of the first mating module 300, the first extension plate 414 can move appropriately in the first recess 1118 along the first direction A1-A1.

Referring to FIG. 15 to FIG. 19, each second ground sheet 42 is generally U-shaped and includes a third mounting plate 421, a fourth mounting plate 422 opposite to the third mounting plate 421, a second connecting plate 423 connecting one side of the third mounting plate 421 and one side of the fourth mounting plate 422, and a second extension plate 424 extending downwardly and backwardly from another side of the fourth mounting plate 422. The third mounting plate 421 defines a plurality of second mounting positioning holes 4211 that match the second positioning posts 1224. The second extension plate 424 is received in a corresponding second recess 1218 of the second conductive housing 12. The second extension plate 424 defines a plurality of second mounting holes 4241 to receive the second mounting protrusions 1219.

The second connecting plate 423 abuts against and at least partially covers the second front surface 220 of the second insulating fixing block 22. The second connecting plate 423 is located at the front end of the first receiving slot 101 along the first direction A1-A1. When the first mating module 300 is inserted, the tongue plate 301 may be in contact with the second connecting plate 423 first, thereby facilitating the discharge of static electricity. The fourth mounting plate 422 is provided with a plurality of second grounding elastic arms 425 which are disposed at intervals along the third direction A3-A3. The second grounding elastic arms 425 are disposed on two sides of the second contact arms 320 of each group of second conductive terminals 32, respectively, so as to improve the shielding effect and improve the quality of signal transmission.

Referring to FIG. 23, the second grounding elastic arm 425 bulges away from the third mounting plate 421 as a whole. Specifically, in the illustrated embodiment of the present disclosure, the second grounding elastic arm 425 includes a second intermediate portion 4250, a third elastic arm portion 4251 connecting one end of the second intermediate portion 4250 and the second connecting plate 423, and a fourth elastic arm portion 4252 connecting another end of the second intermediate portion 4250 and the second extension plate 424. In one embodiment of the present disclosure, the second intermediate portion 4250 includes a second dimple 4250a protruding into the first receiving slot 101. The third elastic arm portion 4251 includes a third contact elastic arm 4251a extending toward the second intermediate portion 4250, and a third relief groove 4251b corresponding to the third contact elastic arm 4251a and providing a deformation space for the third contact elastic arm 4251a. The fourth elastic arm portion 4252 includes a fourth contact elastic arm 4252a extending toward the second intermediate portion 4250, and a fourth relief groove 4252b corresponding to the fourth contact elastic arm 4252a and providing a deformation space for the fourth contact elastic arm 4252a. In the illustrated embodiment of the present disclosure, the third contact elastic arm 4251a and the fourth contact elastic arm 4252a are located on two sides of the second intermediate portion 4250, respectively. The third contact elastic arm 4251a and the fourth contact elastic arm 4252a are aligned along the first direction A1-A1. A free end of the third contact elastic arm 4251a and a free end of the fourth contact elastic arm 4252a are both adjacent to the second intermediate portion 4250. The third contact elastic arm 4251a, the second dimple 4250a and the fourth contact elastic arm 4252a are all in contact with the second ground contact pad 3052 of the first mating module 300. This three-point contact method is beneficial to achieve better shielding effect.

In one embodiment of the present disclosure, the third elastic arm portion 4251 includes a third frame 4251c that is surrounded by all sides. The third relief groove 4251b is a closed groove and is surrounded by the third frame 4251c. The third contact elastic arm 4251a is connected to a wall of the third frame 4251c. The other three walls of the third frame 4251c respectively surround the other three sides of the third contact elastic arm 4251a. In one embodiment of the present disclosure, by arranging the third frame 4251c surrounding the third contact elastic arm 4251a, it can provide better protection for the third contact elastic arm 4251a and prevent the third contact elastic arm 4251a from being excessively deformed.

Similarly, the fourth elastic arm portion 4252 includes a surrounding fourth frame 4252c. The fourth relief groove 4252b is a closed groove and is surrounded by the fourth frame 4252c. The fourth contact elastic arm 4252a is connected to a wall of the fourth frame 4252c. The other three walls of the fourth frame 4252c respectively surround the other three sides of the fourth contact elastic arm 4252a. In one embodiment of the present disclosure, by arranging the fourth frame 4252c surrounding the fourth contact elastic arm 4252a, it can provide better protection for the fourth contact elastic arm 4252a and prevent the fourth contact elastic arm 4252a from being excessively deformed.

In an embodiment of the present disclosure, the second positioning posts 1224 are fixed in the second mounting positioning holes 4211, so that the third mounting plate 421 is fixed to the fourth lower surface 1222 of the second protruding portion 122. As shown in FIG. 20, a dimension of the second mounting hole 4241 along the first direction A1-A1 may be slightly larger than a dimension of the second mounting bump 1219 along the first direction A1-A1. Therefore, when the third contact elastic arm 4251a, the second intermediate portion 4250 and the fourth contact elastic arm 4252a are contacted and deformed by the second ground contact pad 3052 of the first mating module 300, the second extension plate 424 can move appropriately in the second recess 1218 along the first direction A1-A1.

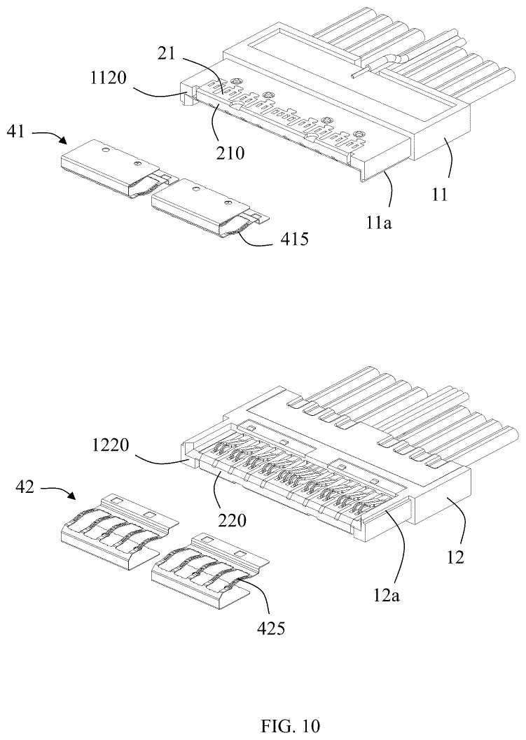

Referring to FIG. 10 to FIG. 19, in the illustrated embodiment of the present disclosure, the first module M1 further includes a first shielding plate 61 installed on the first conductive housing 11 and a first shielding cover 62 installed on the first conductive housing 11. In an embodiment of the present disclosure, the first shielding plate 61 is a metal shielding plate, and the first shielding cover 62 is a metal shielding cover. The first shielding plate 61 includes a first main body portion 611 installed in the first mounting recess 1110 and a plurality of first protrusions 612 integrally stamped from the first main body portion 611. By installing the first shielding plate 61, the downwardly open first mounting grooves 1116 can be better shielded, thereby improving the shielding effect. In the illustrated embodiment of the present disclosure, a lower surface of the first main body portion 611 is flush with the first lower surface 1112 of the first conductive housing 11. The first protrusions 612 protrude into the first terminal module installation slots 113 to be in contact with corresponding first cables 51. In an embodiment of the present disclosure, the first protrusion 612 abuts against the first insulation skin 514 of the first cable 51 to maintain position of the first cable 51. Of course, in other embodiments of the present disclosure, the first protrusion 612 can also abut against the first shielding layer 513 of the first cable 51 to not only maintain the position of the first cable 51, but also improve the grounding shielding effect.

The first shielding cover 62 is installed in the first receiving recess 1114 to cover the first through holes 1117, thereby improving the shielding effect.

In the illustrated embodiment of the present disclosure, the first electrical connector 100 further includes a first ground cable 53. The first ground cable 53 is in contact with the first shielding cover 62. In an embodiment of the present disclosure, the first ground cable 53 is fixed to the first shielding cover 62 by soldering or welding.

Referring to FIG. 10 to FIG. 19, in the illustrated embodiment of the present disclosure, the second module M2 further includes a second shielding plate 63 installed on the second conductive housing 12 and a second shielding cover 64 installed on the second conductive housing 12. In an embodiment of the present disclosure, the second shielding plate 63 is a metal shielding plate, and the second shielding cover 64 is a metal shielding cover. The second shielding plate 63 includes a second main body portion 631 installed in the second mounting recess 1210 and a plurality of second protrusions 632 integrally stamped from the second main body portion 631. By installing the second shielding plate 63, the downwardly open second mounting grooves 1216 can be better shielded, thereby improving the shielding effect. In the illustrated embodiment of the present disclosure, an upper surface of the second main body portion 631 is flush with the third upper surface 1211 of the second conductive housing 12. The second protrusions 632 protrude into the second terminal module installation slots 123 to be in contact with corresponding second cables 52. In one embodiment of the present disclosure, the second protrusion 632 abuts against the second insulation skin 524 of the second cable 52 to maintain the position of the second cable 52. Of course, in other embodiments of the present disclosure, the second protrusion 632 can also abut against the second shielding layer 523 of the second cable 52 to not only maintain the position of the second cable 52, but also improve the grounding shielding effect.

The second shielding cover 64 is installed in the second receiving recess 1214 to cover the second through holes 1217, thereby improving the shielding effect.

In the illustrated embodiment of the present disclosure, the first electrical connector 100 further includes a second ground cable 54. The second ground cable 54 is in contact with the second shielding cover 64. In one embodiment of the present disclosure, the second ground cable 54 is fixed to the second shielding cover 64 by soldering or welding.

When assembling the first electrical connector 100, firstly, the first insulating fixing block 21 is fixed in the first filling grooves 1123, and the second insulating fixing block 22 is fixed in the second filling grooves 1223.

Then, the first terminal modules 31a and the second terminal modules 32a are installed in the corresponding first terminal module installation slots 113 and the second terminal installation slots 123 from back to front along the first direction A1-A1. At this time, the first fixing block 331 and the second fixing block 332 are fixed in the corresponding first terminal module installation slot 113, the first fixing portions 311 of the first conductive terminals 31 are disposed overhead in the corresponding first terminal module installation slot 113, in order to avoid short circuit due to contact with the first conductive housing 11. The first contact arm 310 of the first signal terminal SI at least partially extends into the first slit 211 of the first insulating fixing block 21. The first contact arm 310 of the second signal terminal S2 at least partially extends into the second slit 212 of the first insulating fixing block 21. Similarly, the third fixing block 341 and the fourth fixing block 342 are installed in the corresponding second terminal module installation slot 123, the second fixing portions 321 of the second conductive terminal 32 are disposed overhead in the second terminal module installation slot 123, in order to avoid short circuit due to contact with the second conductive housing 12. The second contact arm 320 of the third signal terminal S3 at least partially extends into the third slit 221 of the second insulating fixing block 22. The second contact arm 320 of the fourth signal terminal S4 at least partially extends into the fourth slit 222 of the second insulating fixing block 22. At this time, the first tail portion 313 of the first conductive terminal 31 is backwardly exposed in the first mounting groove 1116, and the second tail portion 323 of the second conductive terminal 32 is backwardly exposed in the second mounting groove 1216.

Then, the first cables 51 and the second cables 52 are inserted into the corresponding first mounting grooves 1116 and the second mounting grooves 1216 from back to front along the first direction A1-A1. Alternatively, the first cables 51 and the second cables 52 can be disposed in the corresponding first mounting grooves 1116 and the corresponding second mounting grooves 1216 along the second direction A2-A2. The first core 511 of the first cable 51 is in contact with the first tail portion 313 of the first conductive terminal 31. The second core 521 of the second cable 52 is in contact with the second tail portion 323 of the second conductive terminal 32.

In the illustrated embodiment of the present disclosure, the first cables 51 and the second cables 52 are inserted into the corresponding first mounting grooves 1116 and the second mounting grooves 1216 from back to front along the first direction A1-A1. The first core 511 of the first cable 51 is located at a bottom of the first tail portion 313 of the first conductive terminal 31. The second core 521 of the second cable 52 is located on a top of the second tail portion 323 of the second conductive terminal 32. Preferably, in an embodiment of the present disclosure, the first core 511 of the first cable 51 and the first tail 313 of the first conductive terminal 31 are fixed by soldering or welding. The second core 521 of the second cable 52 and the second tail 323 of the second conductive terminal 32 are fixed by soldering or welding.

In order to better perform soldering or welding, in one embodiment of the present disclosure, a first clamp tool (not shown) is provided to extend into the first mounting recess 1110 to support the first cable 51; a second clamp tool (not shown) is provided and inserted into the first through hole 1117 along the second direction A2-A2 to abut against the first tail portion 313 of the first conductive terminal 31. At this time, the first tail portion 313 of the first conductive terminal 31 and the first core 511 of the first cable 51 are clamped between the first clamp tool and the second clamp tool. Therefore, the contact reliability between the first tail portion 313 of the first conductive terminal 31 and the first core 511 of the first cable 51 is improved, and the soldering or welding yield can be improved.

Similarly, in order to better perform soldering or welding, in one embodiment of the present disclosure, a third clamp tool (not shown) is provided and extends into the second mounting recess 1210 to support the second cable 52; and a fourth clamp tool (not shown) is provided and inserted into the second through hole 1217 along the second direction A2-A2 to abut against the second tail portion 323 of the second conductive terminal 32. At this time, the second tail portion 323 of the second conductive terminal 32 and the second core 521 of the second cable 52 are clamped between the third clamp tool and the fourth clamp tool. Therefore, the contact reliability between the second tail portion 323 of the second conductive terminal 32 and the second core 521 of the second cable 52 is improved, and the soldering or welding yield can be improved.

After the soldering or welding process is completed, the first clamp tool, the second clamp tool, the third clamp tool and the fourth clamp tool are removed.

Then, the first shielding plate 61 and the first shielding cover 62 are installed on the first conductive housing 11; and the second shielding plate 63 and the second shielding cover 64 are installed on the second conductive housing 12. The first shielding plate 61 replaces the first clamp tool and fills the position of the first clamp tool during the soldering or welding process of the first cable 51 and the first conductive terminal 31, which avoids the impact of losing supporting to the first cable 51 due to removal of the first clamp tool. The first shielding cover 62 is received in the first receiving recess 1114 to cover the first through holes 1117, thereby improving the shielding effect.

Similarly, the second shielding plate 63 replaces the third clamp tool and fills the position of the third clamp tool during the soldering or welding process of the second cable 52 and the second conductive terminal 32, which avoids the impact of losing supporting to the second cable 52 due to removal of the third clamp tool. The second shielding cover 64 is received in the second receiving recess 1214 to cover the second through holes 1217, thereby improving the shielding effect.

Then, the first ground sheet 41 and the second ground sheet 42 are installed on the first conductive housing 11 and the second conductive housing 12, respectively.

Then, the first conductive housing 11 and the second conductive housing 12 are attached to each other. The first base portion 111 and the second base portion 121 correspond along the top-bottom direction. The first protruding portion 112 and the second protruding portion 122 correspond along the top-bottom direction. The first shielding plate 61 and the second shielding plate 63 are in contact with each other to share a grounding area and improve the grounding shielding effect. In the second direction A2-A2, the first shielding plate 61 and the second shielding plate 63 are located between the plurality of first conductive terminals 31 and the plurality of second conductive terminals 32 to reduce crosstalk between the first conductive terminals 31 and the second conductive terminals 32. Besides, in order to further increase the bonding force of the first conductive housing 11 and the second conductive housing 12, the first conductive housing 11 and the second conductive housing 12 are soldered or welded at the joint position. For example, as shown in FIG. 9, the first conductive housing 11 defines an upwardly recessed first welding groove 11a at the joint position, and the second conductive housing 12 defines a downwardly recessed second welding groove 12a at the joint position. The first welding groove 11a and the second welding groove 12a at corresponding positions are in communication, thereby facilitating filling of solder in the first welding groove 11a and the second welding groove 12a. As a result, the first conductive housing 11 and the second conductive housing 12 are fixed by soldering welding. When the first conductive housing 11 and the second conductive housing 12 are fixed, the first receiving slot 101 for receiving the first mating module 300 is formed between the first protruding portion 112 and the second protruding portion 122.

It is understandable to those skilled in the art that the order of the steps in the above assembly method can be flexibly adjusted as needed, and will not be described again in the present disclosure.

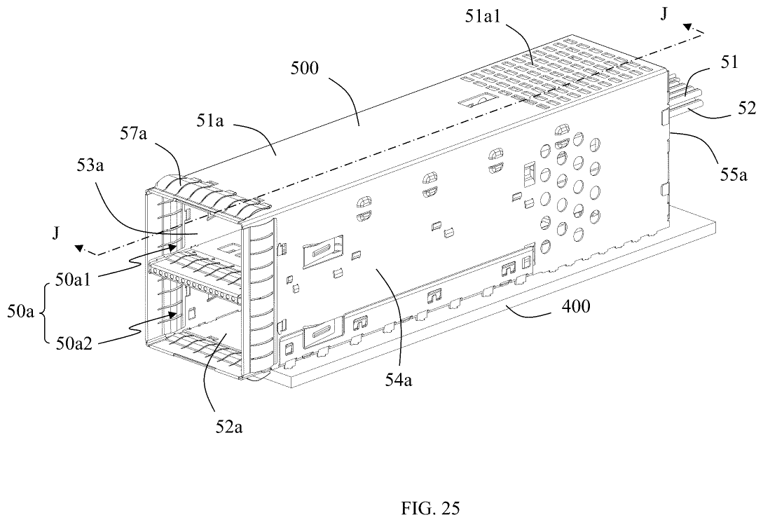

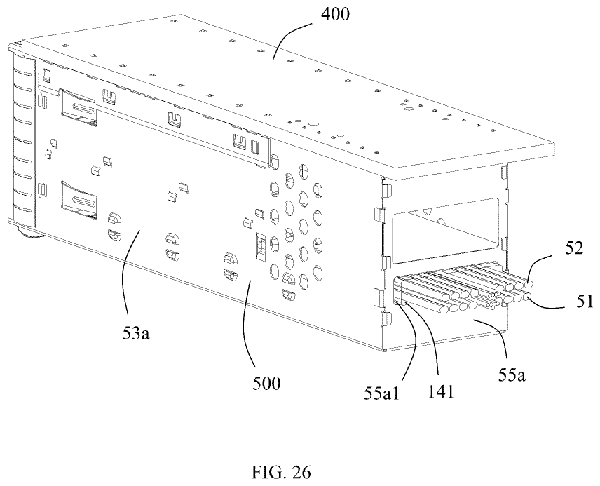

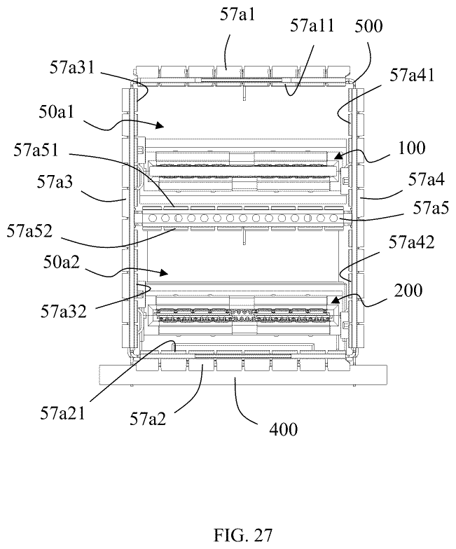

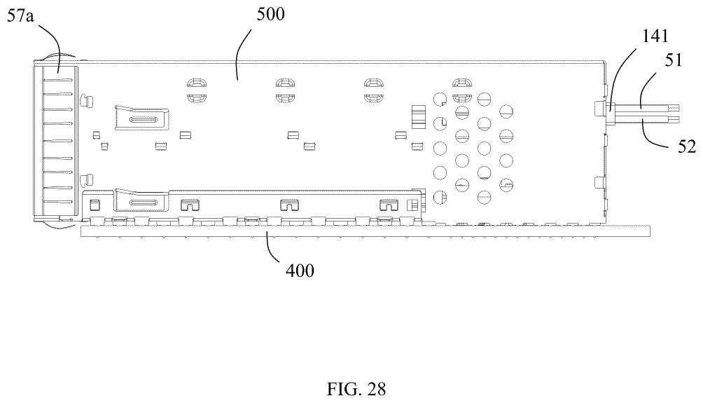

As shown in FIG. 25 to FIG. 34, a second embodiment of the present disclosure discloses another connector assembly, which includes a first electrical connector 100, a second electrical connector 200, a circuit board 400 and a shielding cage 500. The first electrical connector 100 is a cable connector. The second electrical connector 200 is a board-end connector.

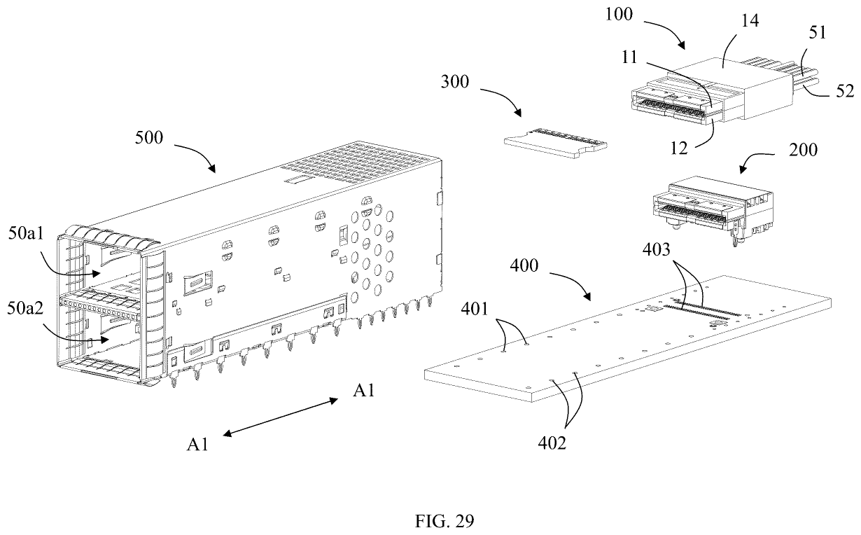

As shown in FIG. 29, the circuit board 400 includes a plurality of first mounting holes 401, a plurality of second mounting holes 402 and a plurality of conductive pads 403. The plurality of first mounting holes 401 are disposed in a first row along the first direction A1-A1. The plurality of second mounting holes 402 are disposed in a second row parallel to the first row along the first direction A1-A1.

The shielding cage 500 is installed and fixed to the circuit board 400. In the second embodiment of the present disclosure, the shielding cage 500 is made of metal material to provide a relatively good shielding effect. The shielding cage 500 includes a first wall portion 51a (for example, a top wall), a second wall portion 52a (for example, a bottom wall) disposed opposite to the first wall portion 51a, a third wall portion 53a (for example, a left side wall), a fourth wall portion 54a (for example, a right side wall) disposed opposite to the third wall portion 53a, and a fifth wall portion 55a (for example, a rear wall). In the illustrated embodiment of the present disclosure, the first wall portion 51a, the third wall portion 53a and the fourth wall portion 54a are integrally formed, in which the third wall portion 53a and the fourth wall portion 54a are vertically bent from two sides of the first wall portion 51a, respectively. In the illustrated embodiment of the present disclosure, the first wall portion 51a, the second wall portion 52a, the third wall portion 53a, the fourth wall portion 54a and the fifth wall portion 55a are jointly enclosed to form a receiving cavity 50a.

Besides, in the illustrated embodiment of the present disclosure, the shielding cage 500 further includes an intermediate wall 56a fixed between the third wall portion 53a and the fourth wall portion 54a. The intermediate wall 56a divides the receiving cavity 50a into a first receiving cavity 50a1 located on one side (for example, an upper side) of the intermediate wall 56a, and a second receiving cavity 50a2 located on another side (for example, a lower side) of the intermediate wall 56a. In the illustrated embodiment of the present disclosure, the intermediate wall 56a includes a first intermediate wall 56a1 and a second intermediate wall 56a2 that are spaced apart from each other, wherein the second intermediate wall 56a2 is located below the first intermediate wall 56a1.

In the illustrated embodiment of the present disclosure, the first receiving cavity 50a1 is jointly enclosed by the first wall portion 51a, an upper half of the third wall portion 53a, an upper half of the fourth wall portion 54a, the first intermediate wall 56a1 and the fifth wall portion 55a. The second receiving cavity 50a2 is jointly enclosed by the second intermediate wall 56a2, the second wall portion 52a, a lower half of the third wall portion 53a, a lower half of the fourth wall portion 54a and the fifth wall portion 55a.

The first wall portion 51a defines a plurality of through holes 51a1 disposed adjacent to the fifth wall portion 55a. In the illustrated embodiment of the present disclosure, the plurality of through holes 51a1 are located above the conductive housing 1 of the first electrical connector 100 to be configured as heat dissipation holes. Of course, it is understandable to those skilled in the art that the heat dissipation holes may be provided on other wall portions of the shielding cage 500.

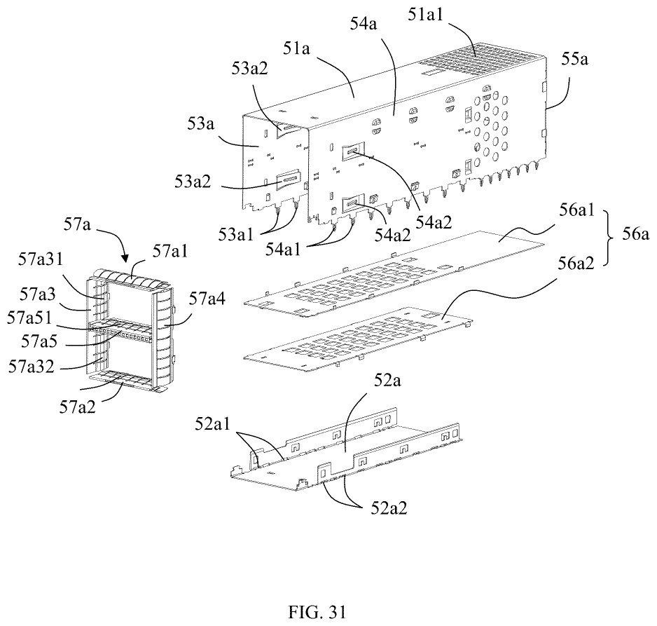

As shown in FIG. 31, the second wall portion 52a defines a plurality of first slits 52a1 and a plurality of second slits 52a2. In the illustrated embodiment of the present disclosure, the second wall portion 52a is generally U-shaped. Two sides of the second wall portion 52a are respectively held by the lower half of the third wall portion 53a and the lower half of the fourth wall portion 54a so as to be fixed with the third wall portion 53a and the fourth wall portion 54a. The plurality of first slits 52a1 are arranged in a row along the first direction A1-A1. The plurality of second slits 52a2 are arranged in another row along the first direction A1-A1.

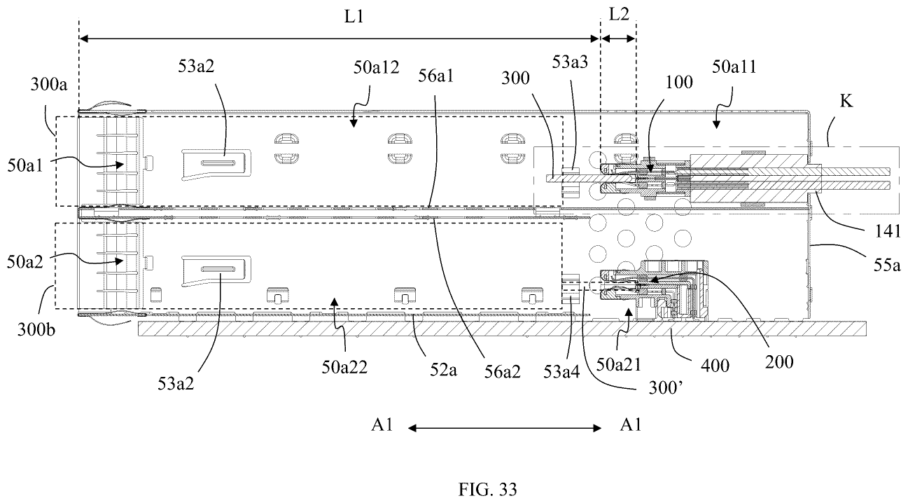

The third wall portion 53a is provided with a plurality of first pressing feet 53a1 extending downwardly and passing through the plurality of first slits 52a1, and a plurality of first abutment tabs 53a2 protruding into the first receiving cavity 50a1 and the second receiving cavity 50a2, respectively. The first pressing foot 53a1 defines a fisheye hole, so that the first pressing foot 53a1 has a certain elastic deformation ability. The first pressing foot 53a1 is configured to pass through the first slit 52a1 and be inserted into the first mounting hole 401 of the circuit board 400 so as to be fixed to the circuit board 400 and achieve grounding. The first abutment tab 53a2 protruding into the first receiving cavity 50a1 is configured to abut against a first mating connector 300a (as shown in FIG. 33) to increase the holding force and improve the grounding effect. The first abutment tab 53a2 protruding into the second receiving cavity 50a2 is configured to abut against a second mating connector 300b (as shown in FIG. 33) to increase the holding force and improve the grounding effect. In the illustrated embodiment of the present disclosure, the first abutment tabs 53a2 are stamped inwardly from the third wall portion 53a.

The fourth wall portion 54a defines a plurality of second pressing feet 54a1 extending downwardly and passing through the plurality of second slits 52a2, and a plurality of second abutment tabs 54a2 protruding into the first receiving cavity 50a1 and the second receiving cavity 50a2, respectively. The second pressing foot 54a1 defines a fisheye hole, so that the second pressing foot 54a1 has a certain elastic deformation ability. The second pressing foot 54a1 is configured to pass through the second slit 52a2 and be inserted into the second mounting hole 402 of the circuit board 400 so as to be fixed to the circuit board 400 and achieve grounding. The second abutment tab 54a2 protruding into the first receiving cavity 50a1 is configured to abut against the first mating connector 300a to increase the holding force and improve the grounding effect. The second abutment tab 54a2 protruding into the second receiving cavity 50a2 is configured to abut against the second mating connector 300b to increase the holding force and improve the grounding effect. In the illustrated embodiment of the present disclosure, the second abutment tabs 54a2 are stamped inwardly from the fourth wall portion 54a.

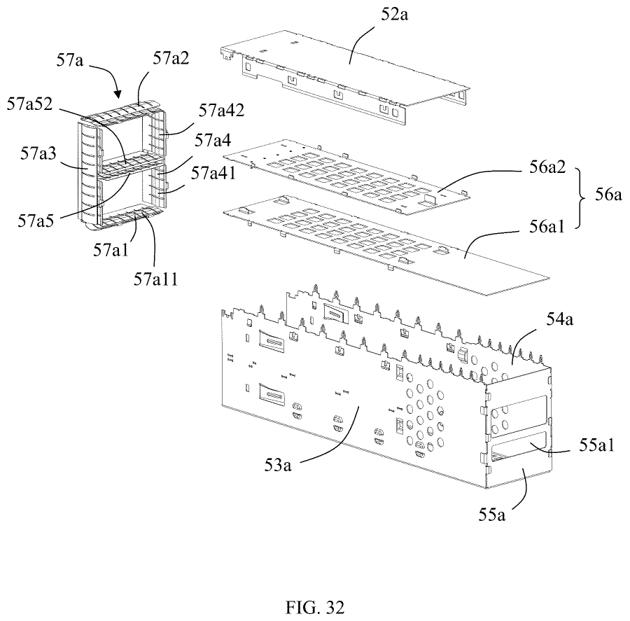

As shown in FIG. 32, the fifth wall portion 55a defines a first opening 55a1 extending through the fifth wall portion 55a along the first direction A1-A1. The first opening 55a1 is in communication with the first receiving cavity 50a1.

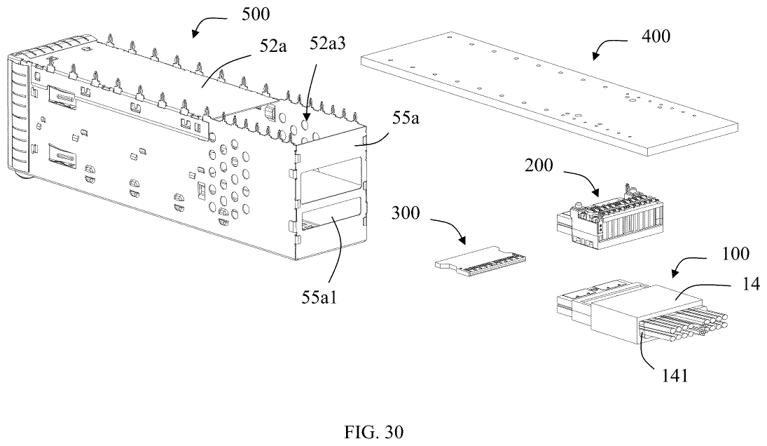

As shown in FIG. 30, a length of the second wall portion 52a extending along the first direction A1-A1 does not reach the fifth wall portion 55a. Therefore, the shielding cage 500 is provided with an installation opening 52a3 located at a rear end of the second wall portion 52a. The installation opening 52a3 is used for allowing the second electrical connector 200 to pass through.

As shown in FIG. 31 and FIG. 32, the shielding cage 500 further includes a plurality of grounding elastic pieces 57a. The plurality of grounding elastic pieces 57a are configured to abut against the first mating connector 300a and the second mating connector 300b to increase the holding force and improve the grounding effect.

Specifically, in the illustrated embodiment of the present disclosure, the plurality of grounding elastic pieces 57a include a first grounding elastic piece 57a1 disposed at a front edge of the first wall portion 51a, a second grounding elastic piece 57a2 disposed at a front edge of the second wall portion 52a, a third grounding elastic piece 57a3 disposed at a front edge of the third wall portion 53a, a fourth grounding elastic piece 57a4 disposed at a front edge of the fourth wall portion 54a, and a fifth grounding elastic piece 57a5 disposed at a front edge of the first intermediate wall 56a1 and a front edge of the second intermediate wall 56a2.

In the illustrated embodiment of the present disclosure, the first grounding elastic piece 57a1 includes a plurality of first elastic piece portions 57a11 protruding into the first receiving cavity 50a1. The second grounding elastic piece 57a2 includes a plurality of second elastic piece portions 57a21 protruding into the second receiving cavity 50a2. The third grounding elastic piece 57a3 includes a plurality of third elastic piece portions 57a31 protruding into the first receiving cavity 50a1 and a plurality of fourth elastic piece portions 57a32 protruding into the second receiving cavity 50a2. The fourth grounding elastic piece 57a4 includes a plurality of fifth elastic piece portions 57a41 protruding into the first receiving cavity 50a1 and a plurality of sixth elastic piece portions 57a42 protruding into the second receiving cavity 50a2. The fifth grounding elastic piece 57a5 includes a plurality of seventh elastic piece portions 57a51 protruding into the first receiving cavity 50a1 and a plurality of eighth elastic piece portions 57a52 protruding into the second receiving cavity 50a2.

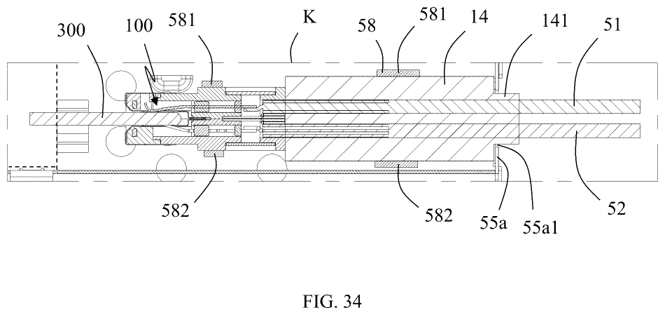

As shown in FIG. 29, FIG. 30, FIG. 33 and FIG. 34, the first electrical connector 100 in the second embodiment of the present disclosure is similar to the first electrical connector 100 in the first embodiment. The difference between the two is that the first electrical connector 100 in the second embodiment of the present disclosure further includes an outer housing 14 fixed on the first conductive housing 11 and the second conductive housing 12. In the illustrated embodiment of the present disclosure, the outer housing 14 is made of insulating material. The outer housing 14 is over-molded on the first cables 51 and the second cables 52 to integrate and fix parts of the first cables 51 and the second cables 52. In the illustrated embodiment of the present disclosure, the outer housing 14 is fixed to the rear ends of the first conductive housing 11 and the second conductive housing 12. The outer housing 14 includes a protrusion 141 at least partially received in the first opening 55a1. By positioning the protrusion 141 in the first opening 55a1, preliminary positioning of the first electrical connector 100 can be achieved.

Referring to FIG. 33, in the illustrated embodiment of the present disclosure, the length of the first receiving cavity 50a1 extending along the first direction A1-A1 is relatively large. The first receiving cavity 50a1 includes a first installation cavity 50a11 located at its rear end, and a first mating cavity 50a12 located at its front end and communicating with the first installation cavity 50a11. The first installation cavity 50a11 is configured to at least partially receive the first electrical connector 100. The first mating cavity 50a12 is configured to at least partially receive the first mating connector 300a. The first mating connector 300a includes the first mating module 300. A length L1 of the first mating cavity 50a12 along the first direction A1-A1 is greater than a length L2 of the first receiving slot 101 along the first direction A1-A1. With this arrangement, the first mating cavity 50a12 is able to provide better shielding effect.

Similarly, the length of the second receiving cavity 50a2 extending along the first direction A1-A1 is relatively large. The second receiving cavity 50a2 includes a second installation cavity 50a21 located at its rear end, and a second mating cavity 50a22 located at its front end and communicating with the second installation cavity 50a21. The second installation cavity 50a21 is configured to at least partially receive the second electrical connector 200. The second mating cavity 50a22 is configured to at least partially receive the second mating connector 300b. The second mating connector 300b is similar to the first mating connector 300a.

It is understandable to those skilled in the art that in order to better maintain the first electrical connector 100 in the first receiving cavity 50a1, avoid hanging in the air. The shielding cage 500 further includes a retaining portion 58 fixed to the third wall portion 53a and the fourth wall portion 54a. The retaining portion 58 protrudes into the first receiving cavity 50a1 to mate with the first electrical connector 100. In the illustrated embodiment of the present disclosure, the retaining portion 58 is provided on the shielding cage 500. Preferably, the retaining portion 58 and the shielding cage 500 are integrally formed. For example, the retaining portion 58 is stamped from the shielding cage 500. It is understandable to those skilled in the art that the retaining portion 58 can also be provided on the first electrical connector 100, including but not limited to be provided on the first conductive housing 11 and/or the second conductive housing 12 of the first electrical connector 100. It is understandable to those skilled in the art that in other embodiments of the present disclosure, a portion of the retaining portion 58 may be provided on the shielding cage 500 and another portion may be provided on the first electrical connector 100. It is understandable to those skilled in the art that the arrangement of the retaining portion 58 can be flexibly adjusted as needed, which will not be described in detail in the present disclosure.

In one embodiment of the present disclosure, the retaining portion 58 includes a first holding piece 581 and a second holding piece 582 which are stamped inwardly from the third wall portion 53a. The first holding piece 581 and the second holding piece 582 are configured to clamp the first electrical connector 100, including but not limited to clamp the outer housing 14 and/or the conductive housing 1 of the first electrical connector 100. It is understandable to those skilled in the art that the first holding piece 581 and the second holding piece 582 can also be stamped inwardly from the fourth wall portion 54a.

In an embodiment illustrated in the present disclosure, the retaining portion 58 is provided to bring the conductive housing 1 of the first electrical connector 100 into contact with the shielding cage 500. The conductive housing 1 and the shielding cage 500 can be connected in series to form a larger ground shielding area, which is conducive to further improving the ground shielding effect and improving the transmission quality of the conductive terminals when transmitting high-speed signals.

Besides, in the illustrated embodiment of the present disclosure, the third wall portion 53a and/or the fourth wall portion 54a are respectively provided with a first limiting protrusion 53a3 and a second limiting protrusion 53a4 which extend into the first mating cavity 50a12 and the second mating cavity 50a22. The first limiting protrusion 53a3 is configured to restrict the position the first mating connector 300a when the first mating connector 300a is inserted into the first mating cavity 50a12. The second limiting protrusion 53a4 is configured to restrict the position of the second mating connector 300b when the second mating connector 300b is inserted into the second mating cavity 50a22. In the illustrated embodiment of the present disclosure, the first limiting protrusion 53a3 and the second limiting protrusion 53a4 are both stamped inwardly from the third wall portion 53a. Of course, it is understandable to those skilled in the art that the first limiting protrusion 53a3 and the second limiting protrusion 53a4 can also be provided on the fourth wall portion 54a, for example, by stamping inwardly from the fourth wall portion 54a.

An installation method of the connector assembly in the second embodiment of the present disclosure is as follows: firstly, the second electrical connector 200 is mounted to the circuit board 400. The conductive terminals of the second electrical connector 200 are electrically connected (for example, soldered or welded) to a plurality of conductive pads 403 of the circuit board 400. Secondly, the assembled shielding cage 500 is mounted to the circuit board 400. The second electrical connector 200 passes through the installation opening 52a3 to be received in the second installation cavity 50a21. At this time, the first pressing feet 53a1 and the second pressing feet 54a1 are inserted and fixed into the first mounting holes 401 and the second mounting holes 402 of the circuit board 400, respectively. Finally, the first electrical connector 100 is installed in the first receiving cavity 50a1 along the first direction A1-A1. The protrusion 141 of the outer housing 14 is received in the first opening 55a1. The first cables 51 and the second cables 52 pass backwardly through the fifth wall portion 55a.

Compared with the prior art, the first tail portion 313 of the first conductive terminal 31 is electrically connected to the first cable 51, and the second tail portion 323 of the second conductive terminal 32 is electrically connected to the second cable 52, which facilitates high-speed signal transmission through the first cable 51 and the second cable 52, thereby being suitable for meeting high-speed signal transmission requirements. Besides, the first electrical connector 100 of the present disclosure is provided with the first conductive housing 11 and the second conductive housing 12. The first conductive terminals 31 are not in contact with the first conductive housing 11. The second conductive terminals 32 are not in contact with the second conductive housing 12. The first conductive housing 11 of the first module M1 and the second conductive housing 12 of the second module M2 are separately arranged and fixed together to jointly form the first receiving slot 101. In addition, the present disclosure also provides the shielding cage 500. With this arrangement, the present disclosure improves the shielding effect on the first conductive terminals 31 and the second conductive terminals 32, and improves the quality of signal transmission.

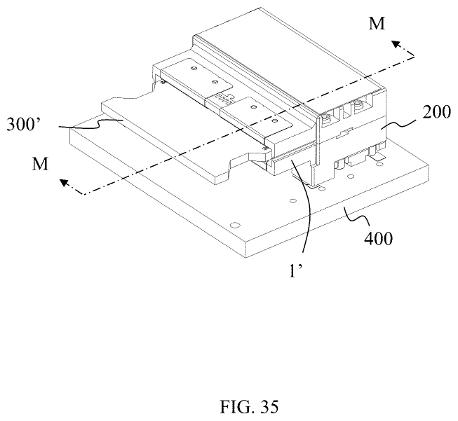

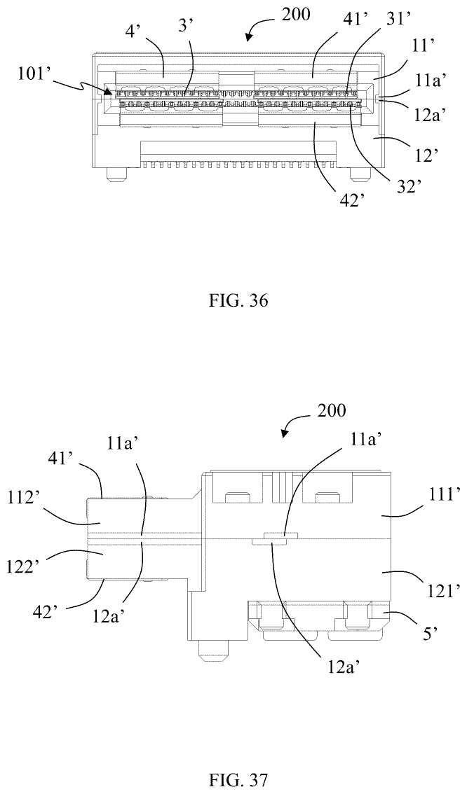

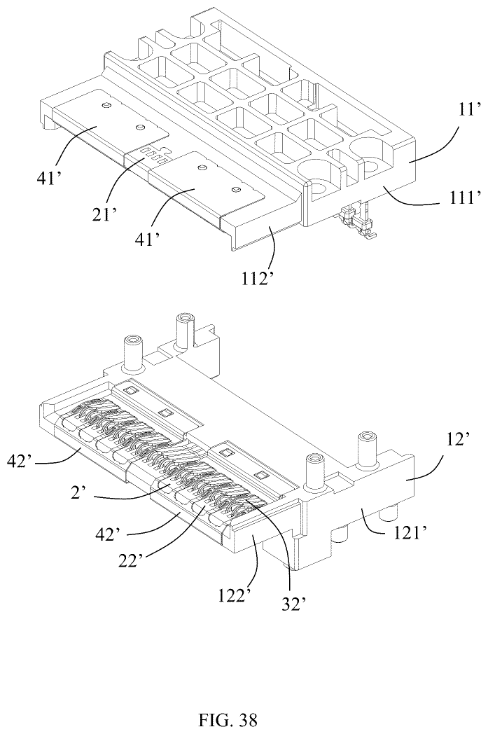

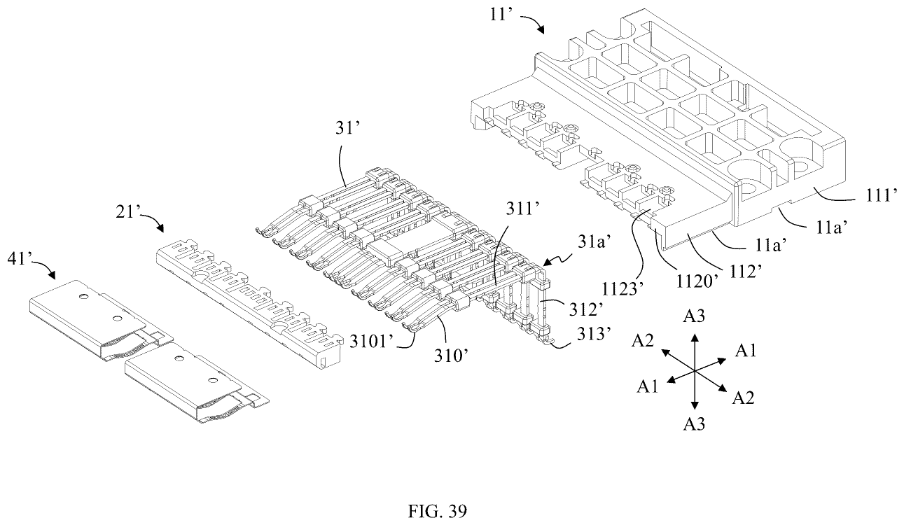

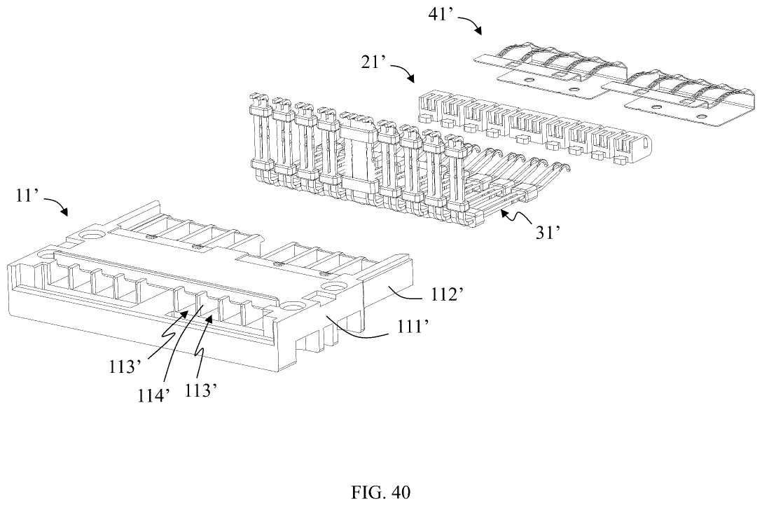

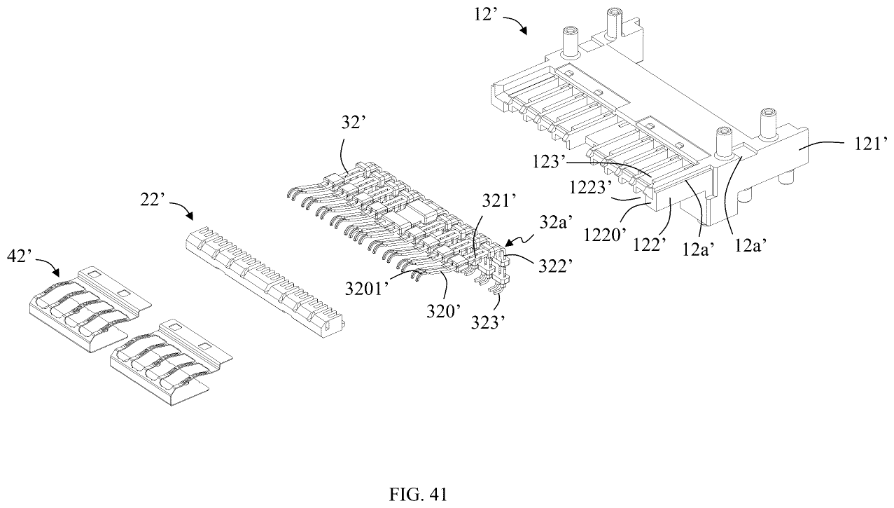

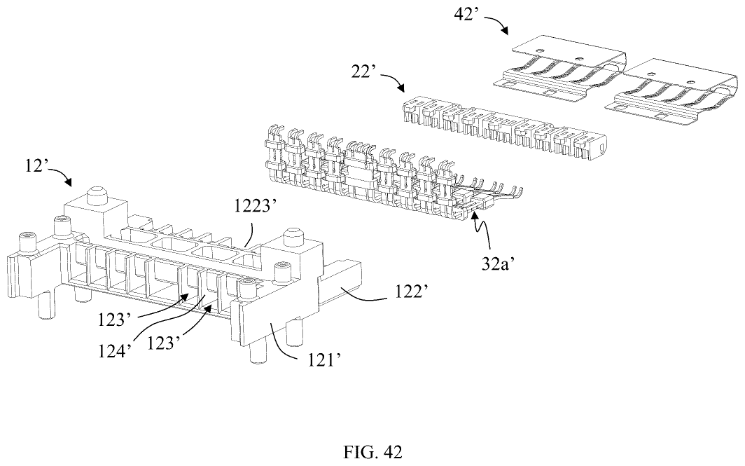

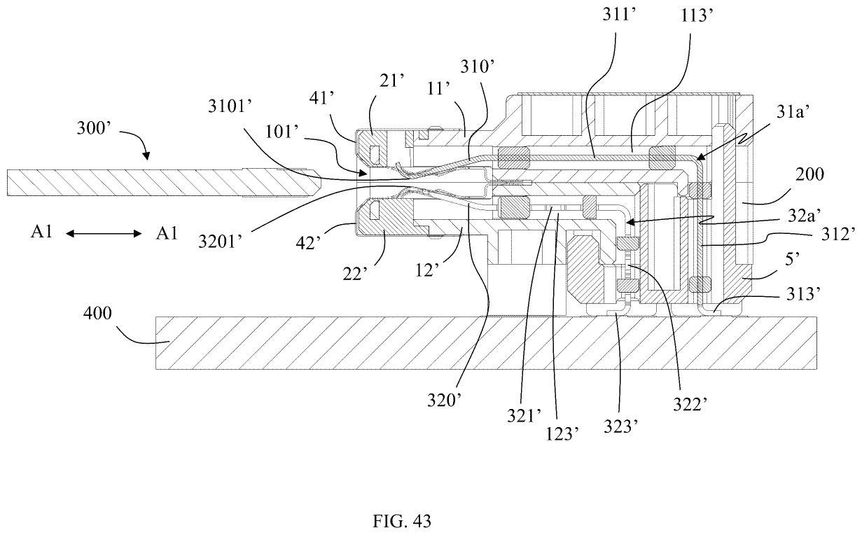

Referring to FIG. 35 to FIG. 43, the present disclosure discloses an embodiment in which the second electrical connector 200 is configured to be installed on the circuit board 400 of another embodiment and mate with a second mating module 300′. In the illustrated embodiment of the present disclosure, the second electrical connector 200 is an OSFP (Octal Small Form-factor Pluggable) receptacle board-end connector. Correspondingly, the second mating module 300′ is an OSFP plug connector. Of course, it is understandable to those skilled in the art that the second electrical connector 200 can also be an SFP (Small Form-factor Pluggable) receptacle connector, a QSFP (Quad Small Form-factor Pluggable) receptacle connector, a QSFP-DD (Quad Small Form-factor Pluggable-Double Density) receptacle connector, an SFP-DD (Small Form-factor Pluggable-Double Density) receptacle connector or a DSFP (Dual Chanel Small Form-factor Pluggable) receptacle connector, etc. Correspondingly, the second mating module 300′ is an SFP plug connector, a QSFP plug connector, a QSFP-DD plug connector, an SFP-DD plug connector or a DSFP plug connector, etc. It is understandable to those skilled in the art that the basic structure of the second electrical connector 200 of the above type is regulated by corresponding association standards, and will not be described in detail here. The second electrical connector 200 and the first electrical connector 100 may be of the same type or different types. Of course, it is understandable to those skilled in the art that the second electrical connector 200 can also be other types of electrical connectors, including but not limited to USB connectors, HDMI connectors, DisplayPort connectors, RJ45 connectors, Thunderbolt connectors, etc.

In the illustrated embodiment of the present disclosure, the second electrical connector 200 defines a second receiving slot 101′ that at least partially receives the second mating module 300′. To maintain consistency in description, the insertion and extraction direction of the second mating module 300′ and the second electrical connector 200 is the first direction A1-A1 (for example, the front-rear direction). The width direction of the second receiving slot 101′ is the second direction A2-A2 (for example, the left-right direction). The installation direction of the second electrical connector 200 and the circuit board 400 is the third direction A3-A3 (for example, the top-bottom direction). In an embodiment of the present disclosure, the second mating module 300′ is the same as the first mating module 300. Of course, in other embodiments of the present disclosure, the second mating module 300′ may also be different from the first mating module 300.

In one embodiment of the present disclosure, the second electrical connector 200 includes a housing, an insulating holding block 2′ fixed to the housing, and a plurality of conductive terminals 3′ mounted to the housing.

In an embodiment of the present disclosure, the housing is a conductive housing 1′. The conductive housing 1′is a metal housing made of metal material to further improve the shielding effect and improve the quality of signal transmission. In another embodiment of the present disclosure, the conductive housing 1′ may also be a composite housing formed by electroplating a metal material on an insulating material. The composite housing can also improve the shielding effect and improve the quality of signal transmission.

In an embodiment of the present disclosure, the conductive housing 1′ includes a third conductive housing 11′ and a fourth conductive housing 12′. The third conductive housing 11′ and the fourth conductive housing 12′ are fixed together. For example, after the third conductive housing 11′ and the fourth conductive housing 12′ are assembled, they are fixed together by soldering, welding or other methods.

In one embodiment of the present disclosure, the third conductive housing 11′ includes a third base portion 111′ and a third protruding portion 112′ extending forwardly from the third base portion 111′. The third protruding portion 112′ defines a plurality of third filling grooves 1123′. Each third filling groove 1123′ extends forwardly through a third front end surface 1120′ of the third protruding portion 112′ along the first direction A1-A1. In the illustrated embodiment of the present disclosure, the third conductive housing 11′ further defines a plurality of third terminal module installation slots 113′ extending along the first direction A1-A1. Each third terminal module installation slot 113′ extends from the third base portion 111′ to the third protruding portion 112′. The plurality of third terminal module installation slots 113′ are spaced apart along the second direction A2-A2. The third conductive housing 11′ includes a plurality of third partition walls 114′ spaced apart along the second direction A2-A2. Two adjacent third terminal module installation slots 113′ are separated by a corresponding third partition wall 114′ along the second direction A2-A2. In other words, each third terminal module installation slot 113′ is surrounded by four walls of the third conductive housing 11′ along a length corresponding to the third partition wall 114′, thereby improving the shielding effect. With this arrangement, each third terminal module installation slot 113′ is relatively independent, thereby reducing signal crosstalk and improving the quality of data transmission.

In an embodiment of the present disclosure, the fourth conductive housing 12′ includes a fourth base portion 121′ and a fourth protruding portion 122′ extending forwardly from the fourth base portion 121′. The fourth protruding portion 122′ defines a plurality of fourth filling grooves 1223′. The fourth filling grooves 1223′ extend forwardly through a fourth front end surface 1220′ of the fourth protruding portion 122′. In the illustrated embodiment of the present disclosure, the fourth conductive housing 12′ further defines a plurality of fourth terminal module installation slots 123′ extending along the first direction A1-A1. Each fourth terminal module installation slot 123′ extends from the fourth base portion 121′ to the fourth protruding portion 122′. The plurality of fourth terminal module installation slots 123′ are spaced apart along the second direction A2-A2. The fourth conductive housing 12′ includes a plurality of fourth partition walls 124′ spaced apart along the second direction A2-A2. Two adjacent fourth terminal module installation slots 123′ are separated by a corresponding fourth partition walls 124′ along the second direction A2-A2. In other words, each fourth terminal module installation slot 123′ is surrounded by four walls of the fourth conductive housing 12′ along a length corresponding to the fourth partition wall 124′, thereby improving the shielding effect. With this arrangement, each fourth terminal module installation slot 123′ is relatively independent, thereby reducing signal crosstalk and improving the quality of data transmission.

In the illustrated embodiment of the present disclosure, the insulating holding block 2′ includes a first insulating holding block 21′ and a second insulating holding block 22′. The first insulating holding block 21′ is fixed in the third filling grooves 1123′. The second insulating holding block 22′ is fixed in the fourth filling grooves 1223′. Preferably, in order to increase the bonding force between the first insulating holding block 21′ and the third conductive housing 11′, the first insulating holding block 21′ is formed in the third filling grooves 1123′. Similarly, in order to increase the bonding force between the second insulating holding block 22′ and the fourth conductive housing 12′, the second insulating holding block 22′ is formed in the fourth filling grooves 1223′.

The plurality of conductive terminals 3′ include a plurality of third conductive terminals 31′ and a plurality of fourth conductive terminals 32′. Each third conductive terminal 31′ includes a third fixing portion 311′ extending along the first direction A1-A1, a third contact arm 310′ extending forwardly from a front end of the third fixing portion 311′, a fourth fixing portion 312′ bent downwardly from a rear end of the third fixing portion 311′, and a first mounting foot 313′ extending from a bottom end of the fourth fixing portion 312′. The third contact arm 310′ is provided with a third contact portion 3101′ that protrudes into the second receiving slot 101′ to be in contact with the second mating module 300′. In the illustrated embodiment of the present disclosure, the first mounting foot 313′ horizontally extends backwardly from the bottom end of the fourth fixing portion 312′ to be electrically connected to the circuit board 400.

Similarly, each fourth conductive terminal 32′ includes a fifth fixing portion 321′ extending along the first direction A1-A1, a fourth contact arm 320′ extending forwardly from a front end of the fifth fixing portion 321′, a sixth fixing portion 322′ bent downwardly from a rear end of the fifth fixing portion 321′, and a second mounting foot 323′ extending from a bottom end of the sixth fixing portion 322′. The fourth contact arm 320′ is provided with a fourth contact portion 3201′ protruding into the second receiving slot 101′ to be in contact with the second mating module 300′. In the illustrated embodiment of the present disclosure, the second mounting foot 323′ horizontally extends forwardly from the bottom end of the sixth fixing portion 322′ to be electrically connected to the circuit board 400.

In an embodiment of the present disclosure, the second electrical connector 200 further includes at least one ground sheet 4′ installed on the conductive housing 1′. The ground sheet 4′ includes a third ground sheet 41′ and a fourth ground sheet 42′. In the illustrated embodiment of the present disclosure, two third ground sheets 41′ are provided and they are made of metal material. Two fourth ground sheets 42′ are provided and they are made of metal material.

In an embodiment of the present disclosure, the second electrical connector 200 further includes a mounting block 5′ installed on the conductive housing 1′. In one embodiment of the present disclosure, the mounting block 5′ is a metal block made of metal material to improve the shielding effect and improve the quality of signal transmission. In another embodiment of the present disclosure, the mounting block 5′ may also be a composite block formed by electroplating metal material on an insulating material.

When assembling the second electrical connector 200, firstly, the first insulating holding block 21′ is fixed in the third filling grooves 1123′, and the second insulating holding block 22′ is fixed in the fourth filling grooves 1223′.

Then, the third conductive housing 11′ and the fourth conductive housing 12′ are assembled together. The third base portion 111′ corresponds to the fourth base portion 121′ along the top-bottom direction; and the third protruding portion 112′ corresponds to the fourth protruding portion 122′ along the top-bottom direction. In order to further increase the bonding force between the third conductive housing 11′ and the fourth conductive housing 12′, the third conductive housing 11′ and the fourth conductive housing 12′ are welded or soldered at a joint position. For example, the third conductive housing 11′ defines an upwardly recessed third welding groove 11a′ at the joint position. The fourth conductive housing 12′ defines a downwardly recessed fourth welding groove 12a′ at the joint position. The third welding groove 11a′ and the fourth welding groove 12a′ at corresponding positions are in communication, which facilitates filling of solder into the third welding groove 11a′ and the fourth welding groove 12a′, thereby the third conductive housing 11′ and the fourth conductive housing 12′ can be fixed by soldering or welding. When the third conductive housing 11′ and the fourth conductive housing 12′ are fixed, the second receiving slot 101′ for receiving the second mating module 300′ is formed between the third protruding portion 112′ and the fourth protruding portion 122′.

Then, the third ground sheet 41′ and the fourth ground sheet 42′ are installed on the third conductive housing 11′ and the fourth conductive housing 12′, respectively.

Then, the third terminal module 31a′ and the fourth terminal module 32a′ are installed in the corresponding third terminal module installation slot 113′ and the fourth terminal module installation slot 123′ from back to front along the first direction A1-A1. The third fixing portion 311′ of the third conductive terminal 31′ is disposed overhead in the third terminal module installation slot 113′ to avoid short circuit due to contact the third conductive housing 11′. The fifth fixing portion 321′ of the fourth conductive terminal 32′ is disposed overhead in the fourth terminal module installation slot 123′ to avoid short circuit due to contact the fourth conductive housing 12′.

Then, the mounting block 5′ is installed on the third conductive housing 11′ and the fourth conductive housing 12′.

It is understandable to those skilled in the art that the order of the steps in the above assembly method can be flexibly adjusted as needed, and will not be described again in the present disclosure.

Compared with the prior art, the second electrical connector 200 of the present disclosure adopts the conductive housing 1′ to replace the insulating body in the related art, thereby improving the shielding effect and improving the quality of signal transmission. Besides, by arranging the third conductive housing 11′ and the fourth conductive housing 12′ separately and fixing them together, the structure of the third conductive housing 11′ and the fourth conductive housing 12′ is simplified. In addition, the present disclosure further provides a shielding cage 500, which improves the shielding effect on the third conductive terminal 31′ and the fourth conductive terminal 32′, and improves the quality of signal transmission.

It is understandable to those skilled in the art that the shielding cage 500 disclosed in the illustrated embodiments of the present disclosure is different from a metal shell fixed on the insulating body in the related art. The disclosed shielding cage 500 in the illustrated embodiments of the present disclosure is basically located on a periphery of the first electrical connector 100 and the second electrical connector 200, but does not emphasize the fixing function with the first electrical connector 100 and the second electrical connector 200. As shown in FIG. 33, the first installation cavity 50a11 provided by the shielding cage 500 for installing the first electrical connector 100 is much larger than a space occupied by the first electrical connector 100 itself. In other words, there is a large space between a top of the first electrical connector 100 and the first wall portion 51a of the shielding cage 500. The first mating cavity 50a12 is configured to accommodate the first mating connector 300a, so as to improve the shielding effect during mating.

Similarly, the second installation cavity 50a21 provided by the shielding cage 500 for installing the second electrical connector 200 is much larger than a space occupied by the second electrical connector 200 itself. In other words, there is a large space between a top of the second electrical connector 200 and the intermediate wall 56a of the shielding cage 500. The second mating cavity 50a22 is configured to accommodate the second mating connector 300b, so as to improve the shielding effect during mating.

In the illustrated embodiment of the present disclosure, the first conductive terminal 31 of the first electrical connector 100 is connected to the first cable 51; the second conductive terminal 32 is connected to the second cable 52; the third conductive terminal 31′ of the second electrical connector 200 is mounted to the circuit board 400; and the fourth conductive terminal 32′ is mounted to the circuit board 400. It is understandable to those skilled in the art that in other embodiments of the present disclosure, the first conductive terminal 31 of the first electrical connector 100 is connected to the first cable 51; the second conductive terminal 32 can be mounted to the circuit board 400; the third conductive terminal 31′ of the second electrical connector 200 is connected to the second cable 52; and the fourth conductive terminal 32′ can be mounted on the circuit board 400.

In the description of the present disclosure, the terms “first”, “second”, “third”, “fourth” and other similar attributives are only used to name components and do not have any quantitative or logical relationship. For example, a general concept of the first electrical connector 100 and the second electrical connector 200 is an electrical connector; a general concept of the first receiving slot 101 and the second receiving slot 101′ is a receiving slot; a general concept of the first conductive housing 11, the second conductive housing 12, the third conductive housing 11′ and the fourth conductive housing 12′ is a conductive housing 1, 1′; and so on.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A connector assembly, comprising:
a first electrical connector, the first electrical connector comprising:
a conductive housing, the conductive housing defining a first receiving slot configured to at least partially receive a first mating connector along a first direction;
a plurality of conductive terminals, the plurality of conductive terminals being at least partially mounted to the conductive housing; each conductive terminal comprising a contact arm; the contact arm comprising a contact portion that at least partially protrudes into the first receiving slot and is configured to be in electrical contact with the first mating connector; and
a plurality of cables, the plurality of cables being electrically connected to the plurality of conductive terminals; and
a shielding cage, the shielding cage being configured to be mounted on a circuit board; the shielding cage defining a first receiving cavity surrounded by a plurality of walls; the first receiving cavity comprising a first installation cavity and a first mating cavity communicating with the first installation cavity along the first direction; the first installation cavity being configured to at least partially receive the first electrical connector; the first mating cavity being configured to at least partially receive the first mating connector;
wherein the connector assembly further comprises a retaining portion provided in the first installation cavity; the retaining portion is configured to support the first electrical connector to retain a portion of the first electrical connector that is located in the first installation cavity in the first installation cavity.

2. The connector assembly according to claim 1, wherein a length of the first mating cavity along the first direction is greater than a length of the first receiving slot along the first direction.

3. The connector assembly according to claim 1, wherein the shielding cage is provided with a first abutment tab protruding into the first mating cavity, and the first abutment tab is configured to abut against the first mating connector.

4. The connector assembly according to claim 1, wherein the shielding cage is provided with a first limiting protrusion protruding into the first mating cavity; the first limiting protrusion is configured to restrict the first mating connector when the first mating connector is inserted into the first mating cavity.

5. The connector assembly according to claim 1, wherein the first electrical connector comprises:
a first module comprising:
a first conductive housing; and
a first terminal module, the first terminal module being at least partially provided on the first conductive housing; the first terminal module comprising a plurality of first conductive terminals; each first conductive terminal comprising a first contact arm and a first tail portion; the first contact arm comprising a first contact portion configured to be in contact with a first mating module to achieve electrical connection; and
a second module comprising:
a second conductive housing; and
a second terminal module, the second terminal module being at least partially provided on the second conductive housing; the second terminal module comprising a plurality of second conductive terminals; each second conductive terminal comprising a second contact arm and a second tail portion; the second contact arm comprising a second contact portion configured to be in contact with the first mating module to achieve electrical connection;
wherein the first conductive housing of the first module and the second conductive housing of the second module are separately arranged and fixed together to jointly form a first receiving slot; the first receiving slot is configured to at least partially receive the first mating module along the first direction; the first contact portions of the first conductive terminals and the second contact portions of the second conductive terminals protrude into the first receiving slot; and
wherein the conductive housing comprises the first conductive housing and the second conductive housing; the plurality of conductive terminals comprise the plurality of first conductive terminals and the plurality of second conductive terminals; the contact arm comprises the first contact arm and the second contact arm; the contact portion comprises the first contact portion and the second contact portion.

6. The connector assembly according to claim 5, wherein the electrical connector comprises a plurality of cables which are connected to the first tail portions and/or the second tail portions.

7. The connector assembly according to claim 6, wherein the first conductive housing defines a first terminal module installation slot and a first mounting groove communicating with the first terminal module installation slot; the first tail portion at least partially extends into the first mounting groove;
the second conductive housing defines a second terminal module installation slot and a second mounting groove communicating with the second terminal module installation slot; the second tail portion at least partially extends into the second mounting groove;
the plurality of cables comprise a plurality of first cables and a plurality of second cables; the first cables are at least partially disposed in the first mounting groove and electrically connected to the first tail portions of the first conductive terminals; the second cables are at least partially disposed in the second mounting groove and electrically connected to the second tail portions of the second conductive terminals.

8. The connector assembly according to claim 7, wherein the shielding cage comprises a first wall portion, an intermediate wall disposed opposite to the first wall portion, a third wall portion, and a fourth wall portion disposed opposite to the third wall portion; the first receiving cavity is circumferentially surrounded by the first wall portion, the third wall portion, the fourth wall portion and the intermediate wall.

9. The connector assembly according to claim 8, wherein the retaining portion comprises a first holding piece and a second holding piece which are stamped inwardly from the third wall portion and/or the fourth wall portion; the first holding piece and the second holding piece are configured to clamp the first electrical connector to retain the portion of the first electrical connector that is located in the first installation cavity in the first installation cavity.

10. The connector assembly according to claim 8, wherein the shielding cage further comprises a fifth wall portion; the fifth wall portion is located at one end of the first receiving cavity along the first direction; the fifth wall portion defines a first opening extending through the fifth wall portion along the first direction; the first opening communicates with the first installation cavity;
the plurality of first cables and the plurality of second cables pass through the fifth wall portion from the first opening.

11. The connector assembly according to claim 10, wherein the first electrical connector comprises an outer housing fixed to the first conductive housing, the second conductive housing, the plurality of first cables and the plurality of second cables; the outer housing comprises a protrusion at least partially received in the first opening.

12. The connector assembly according to claim 8, wherein the circuit board defines a plurality of first mounting holes and a plurality of second mounting holes;
the third wall portion comprises a plurality of first press-fit feet configured to be inserted into the first mounting holes;
the fourth wall portion comprises a plurality of second press-fit feet configured to be inserted into the second mounting holes.

13. The connector assembly according to claim 8, wherein the shielding cage further comprises a plurality of grounding elastic pieces; the plurality of grounding elastic pieces comprise a first grounding elastic piece provided at a front edge of the first wall portion, a third grounding elastic piece provided at a front edge of the third wall portion, a fourth grounding elastic piece provided at a front edge of the fourth wall portion, and a fifth grounding elastic piece provided at a front edge of the intermediate wall;
the first grounding elastic piece is provided with a plurality of first elastic piece portions protruding into the first mating cavity; the third grounding elastic piece is provided with a plurality of third elastic piece portions protruding into the first mating cavity; the fourth grounding elastic piece is provided with a plurality of fifth elastic piece portions protruding into the first mating cavity; the fifth grounding elastic piece is provided with a plurality of seventh elastic piece portions protruding into the first mating cavity; the plurality of first elastic piece portions, the plurality of third elastic piece portions, the plurality of fifth elastic piece portions and the plurality of seventh elastic piece portions are all configured to abut against the mating connector.

14. The connector assembly according to claim 5, wherein the first module comprises a first shielding plate installed on the first conductive housing;
the second module comprises a second shielding plate installed on the second conductive housing;
wherein the first shielding plate and the second shielding plate are in contact with each other; the first shielding plate and the second shielding plate are located between the plurality of first conductive terminals and the plurality of second conductive terminals along a second direction; and the second direction is perpendicular to the first direction.

15. The connector assembly according to claim 5, wherein the first module and the second module are a same module with different installation angles.

16. A connector assembly, comprising:
a first electrical connector, the first electrical connector comprising:
a conductive housing, the conductive housing defining a first receiving slot configured to at least partially receive a first mating connector along a first direction;
a plurality of conductive terminals, the plurality of conductive terminals being at least partially assembled to the conductive housing; each conductive terminal comprising a contact arm; the contact arm comprising a contact portion that at least partially protrudes into the first receiving slot and is configured to be in electrical contact with the first mating connector; and
a plurality of cables, the plurality of cables being electrically connected to the plurality of conductive terminals; and
a shielding cage, the shielding cage being configured to be mounted to a circuit board; the shielding cage defining a first receiving cavity surrounded by a plurality of walls; the first receiving cavity comprising a first installation cavity and a first mating cavity communicating with the first installation cavity along the first direction; the first installation cavity being configured to at least partially receive the first electrical connector along a second direction perpendicular to the first direction; the first mating cavity and the first receiving slot being configured to jointly at least partially receive the first mating connector;
wherein the connector assembly further comprises a retaining portion extending into the first installation cavity; the retaining portion is configured to clamp the first electrical connector to secure the first electrical connector in the first installation cavity.

17. The connector assembly according to claim 16, wherein a length of the first mating cavity along the first direction is greater than a length of the first receiving slot along the first direction.

18. The connector assembly according to claim 16, wherein the shielding cage is provided with a first abutment tab protruding into the first mating cavity, and the first abutment tab is configured to abut against the first mating connector.

19. The connector assembly according to claim 16, wherein the shielding cage is provided with a first limiting protrusion protruding into the first mating cavity; the first limiting protrusion is configured to restrict the first mating connector when the first mating connector is inserted into the first mating cavity.

20. The connector assembly according to claim 16, wherein the first electrical connector comprises:
a first module comprising:
a first conductive housing; and
a first terminal module, the first terminal module being at least partially provided on the first conductive housing; the first terminal module comprising a plurality of first conductive terminals; each first conductive terminal comprising a first contact arm and a first tail portion; the first contact arm comprising a first contact portion configured to be in contact with a first mating module to achieve electrical connection; and
a second module comprising:
a second conductive housing; and
a second terminal module, the second terminal module being at least partially provided on the second conductive housing; the second terminal module comprising a plurality of second conductive terminals; each second conductive terminal comprising a second contact arm and a second tail portion; the second contact arm comprising a second contact portion configured to be in contact with the first mating module to achieve electrical connection;
wherein the first conductive housing of the first module and the second conductive housing of the second module are separately arranged and fixed together to jointly form a first receiving slot; the first receiving slot is configured to at least partially receive the first mating module along the first direction; the first contact portions of the first conductive terminals and the second contact portions of the second conductive terminals protrude into the first receiving slot; and
wherein the conductive housing comprises the first conductive housing and the second conductive housing; the plurality of conductive terminals comprise the plurality of first conductive terminals and the plurality of second conductive terminals; the contact arm comprises the first contact arm and the second contact arm; the contact portion comprises the first contact portion and the second contact portion;
wherein the electrical connector comprises a plurality of cables which are connected to the first tail portions and/or the second tail portions.
